(19) United States
(12) Patent Application Publication
(10) Pub. No.: US 2025/0318375 A1
(43) Pub. Date: Oct. 9, 2025

(54) DISPLAY DEVICE

(71) Applicant: Samsung Display Co., Ltd., Yongin-si (KR)

(72) Inventors: HANSOL KIM, Yongin-si (KR); JOONG-SOO MOON, Yongin-si (KR); CHANG-YEOL LEE, Yongin-si (KR); YOUNGJIN CHO, Yongin-si (KR); EUNBYUL JO, Yongin-si (KR)

(21) Appl. No.: 18/965,932

(22) Filed: Dec. 2, 2024

(30) Foreign Application Priority Data
Apr. 3, 2024 (KR) 10-2024-0045426

(51) Int. Cl. H10K 59/131

(52) U.S. Cl. CPC H10K 59/131

(57) ABSTRACT

A display device includes: pixels in a display area; scan lines connected to the pixels; data lines connected to the pixels; vertical initialization lines connected to the pixels; and a common line in a non-display area around the display area. The display area includes: a first side extending in a first direction; a second side adjacent to one end of the first side, and extending in a second direction crossing the first direction; and a first rounded corner connecting the one end of the first side to one end of the second side that is adjacent to the one end of the first side. The common line is adjacent to the first side and the first rounded corner, and the vertical initialization lines are adjacent to the first side and the first rounded corner, are connected to the common line, and extend from the common line in the second direction.

### CROSS-REFERENCE TO RELATED APPLICATION

The present application claims priority to and the benefit of Korean Patent Application No. 10-2024-0045426, filed on Apr. 3, 2024, in the Korean Intellectual Property Office, the entire disclosure of which is incorporated by reference herein.

### BACKGROUND

### 1. Field

Aspects of embodiments of the present disclosure relate to a display device.

### 2. Description of the Related Art

Generally, electronic devices, such as smart phones, digital cameras, laptop computers, navigation devices, and smart televisions, which provide images to users, include display devices for displaying the images. The display device generates the image, and provides the generated image to a user through a display screen.

The display device includes a plurality of pixels for generating the images, and a plurality of lines connected to the pixels. The pixels are driven by receiving driving signals through the lines.

The above information disclosed in this Background section is for enhancement of understanding of the background of the present disclosure, and therefore, it may contain information that does not constitute prior art.

### SUMMARY

Recently, with the development of display devices having various shapes, the display devices may have a rounded corner quadrangular shape in which the corners of the quadrangular shape are rounded. A display area of the display device may also have a rounded corner quadrangular shape depending on a desired shape of the display device. As such, it may be desirable to more easily connect the lines to the pixels disposed at the rounded corners.

One or more embodiments of the present disclosure may be directed to a display device having an improved display quality by uniformly forming line resistances for pixels in a display area.

According to one or more embodiments of the present disclosure, a display device includes: a plurality of pixels in a display area; a plurality of scan lines connected to the pixels; a plurality of data lines connected to the pixels; a plurality of vertical initialization lines connected to the pixels; and a common line in a non-display area around the display area. The display area includes: a first side extending in a first direction; a second side adjacent to one end of the first side, and extending in a second direction crossing the first direction; and a first rounded corner connecting the one end of the first side to one end of the second side that is adjacent to the one end of the first side. The common line is adjacent to the first side and the first rounded corner, and the vertical initialization lines are adjacent to the first side and the first rounded corner, are connected to the common line, and extend from the common line in the second direction.

In an embodiment, the common line may not be located in the non-display area adjacent to the second side.

In an embodiment, the common line may include: a first common line in the non-display area, and adjacent to the first side; and a (2-1)^{th} common line in the non-display area, and adjacent to the first rounded corner.

In an embodiment, the first common line may extend in the first direction, and the (2-1)^{th} common line may extend from the first common line, and may have a curved shape corresponding to the first rounded corner.

In an embodiment, the first common line may be connected to a pad configured to receive an initialization voltage.

In an embodiment, the display device may further include a scan driver in the non-display area, adjacent to the second side and the first rounded corner, and connected to the scan lines.

In an embodiment, the (2-1)^{th} common line may be located between the scan driver and the first rounded corner.

In an embodiment, the display device may further include: a repair initialization line extending from the first common line between the display area and the scan lines; and a repair pixel circuit between the display area and the scan lines, and located adjacent to the scan driver. The repair initialization line may be connected to the repair pixel circuit.

In an embodiment, the display area may further include: a third side adjacent to another end of the first side, and extending in the second direction; and a second rounded corner connecting the other end of the first side to one end of the third side adjacent to the other end of the first side. The common line may further include a (2-2)^{th} common line in the non-display area, and adjacent to the second rounded corner. The vertical initialization lines may be further located adjacent to the second rounded corner, may be connected to the (2-2)^{th} common line, and may extend from the (2-2)^{th} common line in the second direction.

In an embodiment, the common line may not be located in the non-display area adjacent to the third side.

In an embodiment, the (2-2)^{th} common line may extend from the first common line, and may have a curved shape corresponding to the second rounded corner.

In an embodiment, the display device may further include: a plurality of light emitting lines connected to the pixels; and a light emission driver in the non-display area, adjacent to the third side and the second rounded corner, and connected to the light emitting lines.

In an embodiment, the (2-2)^{th} common line may be located between the light emission driver and the second rounded corner.

In an embodiment, the display device may further include a plurality of horizontal initialization lines in the display area, and extending to cross the vertical initialization lines.

In an embodiment, the horizontal initialization lines may be connected to the vertical initialization lines and to the pixels.

In an embodiment, the vertical initialization lines and the horizontal initialization lines may be located at different layers from each other.

In an embodiment, the vertical initialization lines may be located above the horizontal initialization lines.

In an embodiment, the common line may surround around the display area, and the vertical initialization lines and the horizontal initialization lines may extend to the non-display area, and may be connected to the common line.

According to one or more embodiments of the present disclosure, a display device includes: a plurality of pixels in a display area; a plurality of scan lines connected to the pixels; a plurality of data lines connected to the pixels; a common line in a non-display area around the display area; and a plurality of vertical initialization lines connected to the pixels. The display area includes: a first side extending in a first direction; a second side and a third side adjacent to opposite ends of the first side, and extending in a second direction crossing the first direction; a first rounded corner connecting the first side and the second side to each other; and a second rounded corner connecting the first side and the second side to each other. The common line is adjacent to the first side, the first rounded corner, and the second rounded corner. The vertical initialization lines are adjacent to the first side, the first rounded corner, and the second rounded corner, are connected to the common line, and extend from the common line in the second direction.

In an embodiment, the common line may not be located in a non-display area adjacent to each of the second side and the third side.

According to one or more embodiments of the present disclosure, a display device includes: a plurality of pixels located inside a display area, the display area including: sides of a quadrangle extending in a first direction and a second direction crossing the first direction; and rounded corners connecting the sides to one another; a plurality of scan lines connected to the pixels; a plurality of data lines connected to the pixels; a common line in a non-display area around the display area, and adjacent to at least one side and at least one rounded corner that are adjacent to each other from among the sides and the rounded corners; and a plurality of vertical initialization lines adjacent to the at least one side and the at least one rounded corner, and connected to the pixels and the common line. The vertical initialization lines extend from the common line in a direction crossing an extension direction of the at least one side.

### BRIEF DESCRIPTION OF THE DRAWINGS

The above and other aspects and features of the present disclosure will be more clearly understood from the following detailed description of the illustrative, non-limiting embodiments with reference to the accompanying drawings.

FIG. 1 is a perspective view of a display device according to an embodiment of the present disclosure.

FIG. 2 is a view schematically illustrating a cross section of the display device illustrated in FIG. 1.

FIG. 3 is a view schematically illustrating a cross section of a display panel illustrated in FIG. 2.

FIG. 4 is a block diagram of the display device illustrated in FIG. 1.

FIG. 5 is a view illustrating an equivalent circuit of any one pixel illustrated in FIG. 4.

FIG. 6 is a timing diagram of scan signals and light emitting signals for an operation of the pixel illustrated in FIG. 5.

FIG. 7 is a view schematically illustrating a cross section of a light emitting element, a first transistor, a fourth transistor, and a sixth transistor of the pixel illustrated in FIG. 5.

FIG. 8 is a plan view of the display panel illustrated in FIG. 4.

FIG. 9 is a view separately illustrating a configuration of a first initialization line disposed on the display panel illustrated in FIG. 8.

FIG. 10 is a view separately illustrating a configuration of a second initialization line disposed on the display panel illustrated in FIG. 8.

FIG. 11A is an enlarged view of a portion of the display panel adjacent to a first rounded corner illustrated in FIG. 9.

FIG. 11B is an enlarged view of a portion of the display panel adjacent to a second rounded corner illustrated in FIG. 9.

FIGS. 11C and 11D are enlarged views of portions of the display panel adjacent to third rounded corners illustrated in FIG. 9.

FIG. 12A is a plan view illustrating a connection configuration between the first and second initialization lines and the pixels at a center of the display panel.

FIG. 12B is a plan view illustrating a connection configuration between the first and second initialization lines and the pixels adjacent to the first rounded corner.

FIG. 13 is a view illustrating a cross section of a first vertical initialization line and a first horizontal initialization line corresponding to one contact hole illustrated in FIG. 9.

FIG. 14 is a view illustrating a configuration of a display panel according to a comparative example.

FIGS. 15-17 are views illustrating configurations of common lines according to one or more embodiments of the present disclosure.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

Further, as would be understood by a person having ordinary skill in the art, in view of the present disclosure in its entirety, each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner, unless otherwise stated or implied.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

Further, it should be expected that the shapes shown in the figures may vary in practice depending, for example, on tolerances and/or manufacturing techniques. Accordingly, the embodiments of the present disclosure should not be construed as being limited to the specific shapes shown in the figures, and should be construed considering changes in shapes that may occur, for example, as a result of manufacturing. As such, the shapes shown in the drawings may not depict the actual shapes of areas of the device, and the present disclosure is not limited thereto.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

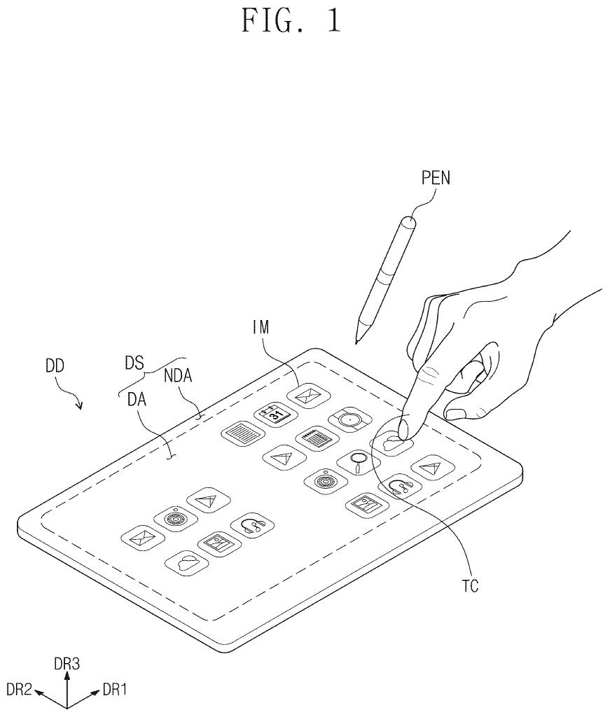

FIG. 1 is a perspective view of a display device according to an embodiment of the present disclosure.

Referring to FIG. 1, a display device DD according to an embodiment of the present disclosure may have long sides extending in a first direction DR1 and in parallel with each other, and short sides extending in a second direction DR2 crossing or intersecting the first direction DR1 and in parallel with each other. Corners of the display device DD, which connect the long sides and the short sides to each other, may have a curved shape (e.g., a rounded shape). The corners of the display device DD having the curved shape may be defined as rounded corners. The shape of the display device DD may be defined as a rounded corner quadrangular shape.

Hereinafter, a direction perpendicular to or substantially perpendicular to a plane defined by the first direction DR1 and the second direction DR2 is defined as a third direction DR3. Further, as used in the specification, the phrases “when viewed on a plane” and “in a plan view” are defined as a state of being viewed from the third direction DR3.

The front surface of the display device DD may be defined as a display surface DS, and may have the plane defined by the first direction DR1 and the second direction DR2. Images IM generated by the display device DD may be provided to a user through the display surface DS.

The display surface DS may include a display area DA, and a non-display area NDA around the display area DA. The display area DA displays an image, and the non-display area NDA does not display the image. The non-display area NDA may surround (e.g., around a periphery of) the display area DA, and may define an edge of the display device DD, which may be printed in a suitable color (e.g., a predetermined color).

The display area DA may have a rounded corner quadrangular shape according to the desired shape of the display device DD. For example, the display area DA may include sides of a quadrangle extending in the first direction DR1 and the second direction DR2, and rounded corners connecting the sides to each other. The sides extending in the first direction DR1 from among the four sides may be defined as long sides, and the sides extending in the second direction DR2 from among the four sides may be defined as short sides.

The display device DD may sense inputs applied from the outside of the display device DD. For example, the display device DD may sense a first input by a touch pen PEN, and a second input by a touch TC. The touch pen PEN may be defined as an input device.

The touch pen PEN may be an active pen that outputs a signal. The second input by the touch TC may include various suitable kinds of external inputs, such as a portion of a body of the user, light, heat, or pressure.

The display device DD and the touch pen PEN may bidirectionally communicate with each other. The display device DD may provide an uplink signal to the touch pen PEN. For example, the uplink signal may include desired information, such as panel information and a protocol version, but the present disclosure is not limited thereto.

The touch pen PEN may provide a downlink signal to the display device DD. The downlink signal may include a synchronization signal and/or status information of the touch pen PEN. For example, the downlink signal may include coordinate information of the touch pen PEN, battery information of the touch pen PEN, inclination information of the touch pen PEN, and/or various pieces of information stored in the touch pen PEN, but the present disclosure is not particularly limited thereto.

The display device DD may be used for large-sized electronic devices, such as televisions, monitors, or external billboards. Further, the display device DD may be used for small-sized or medium-sized electronic devices, such as a personal computer (PC), a laptop, a personal digital terminal, a vehicle navigation system, a game console, a smart phone, a tablet PC, or a camera. However, the present disclosure is not limited thereto, and the display device DD may be used for other suitable electronic devices, as long as the other electronic devices include the display device DD according to one or more embodiments.

FIG. 2 is a view schematically illustrating a cross section of the display device illustrated in FIG. 1.

Illustratively, FIG. 2 is a cross-sectional view of the display device DD when viewed in the second direction DR2.

Referring to FIG. 2, the display device DD may include a display panel DP, an input sensing unit (e.g., an input sensing part or layer) ISP, a reflection preventing layer RPL, a window WIN, a panel protecting film PPF, and first and second adhesive layers AL1 and AL2.

The display panel DP according to an embodiment of the present disclosure may be a light emitting display panel. For example, the display panel DP may be an organic light emitting display panel or an inorganic light emitting display panel. A light emitting layer of the organic light emitting display panel may include an organic light emitting material. A light emitting layer of the inorganic light emitting display panel may include a quantum dot and/or a quantum rod. Hereinafter, the display panel DP will be described in more detail in the context of the organic light emitting display panel for convenience of illustration.

The input sensing unit ISP may be disposed on the display panel DP. The input sensing unit ISP may include a plurality of sensing units (e.g., a plurality of sensors or sensor electrodes) for sensing an external input in a capacitive manner. The input sensing unit ISP may be directly manufactured on the display panel DP when the display device DD is manufactured. However, the present disclosure is not limited thereto, and the input sensing unit ISP may be manufactured as a separate panel from the display panel DP, and may be attached to the display panel DP by an adhesive layer.

The reflection preventing layer RPL may be disposed on the input sensing unit ISP. The reflection preventing layer RPL may be directly manufactured on the input sensing unit ISP when the display device DD is manufactured. However, the present disclosure is not limited thereto, and the reflection preventing layer RPL may be manufactured as a separate panel, and may be attached to the input sensing unit ISP by an adhesive layer.

The reflection preventing layer RPL may be defined as an external light reflection preventing film. The reflection preventing layer RPL may reduce a reflectance of external light input from an upper side of the display device DD toward the display panel DP. The external light may not be visually recognized by the user due to the reflection preventing layer RPL.

When external light traveling toward the display panel DP is reflected by the display panel DP and provided back to an external user, the user may visually recognize the external light like a mirror. To prevent or substantially prevent such a phenomenon, illustratively, the reflection preventing layer RPL may include a plurality of color filters that display the same or substantially the same colors as those of the pixels of the display panel DP.

The color filters may filter the external light into the same or substantially the same colors as those of the pixels. In this case, the external light may not be visually recognized by the user. However, the present disclosure is not limited thereto, and the reflection preventing layer RPL may include a phase retarder and/or a polarizer to reduce the reflectance of the external light.

The window WIN may be disposed on the reflection preventing layer RPL. The window WIN may protect the display panel DP, the input sensing unit ISP, and the reflection preventing layer RPL from external scratches and impacts.

The panel protecting film PPF may be disposed under the display panel DP. The panel protecting film PPF may protect a lower portion of the display panel DP. The panel protecting film PPF may include a flexible plastic material, such as polyethyleneterephthalate (PET).

The first adhesive layer AL1 may be disposed between the display panel DP and the panel protecting film PPF, and the display panel DP and the panel protecting film PPF may be adhered to each other by the first adhesive layer AL1. The second adhesive layer AL2 may be disposed between the window WIN and the reflection preventing layer RPL, and the window WIN and the reflection preventing layer RPL may be adhered to each other by the second adhesive layer AL2.

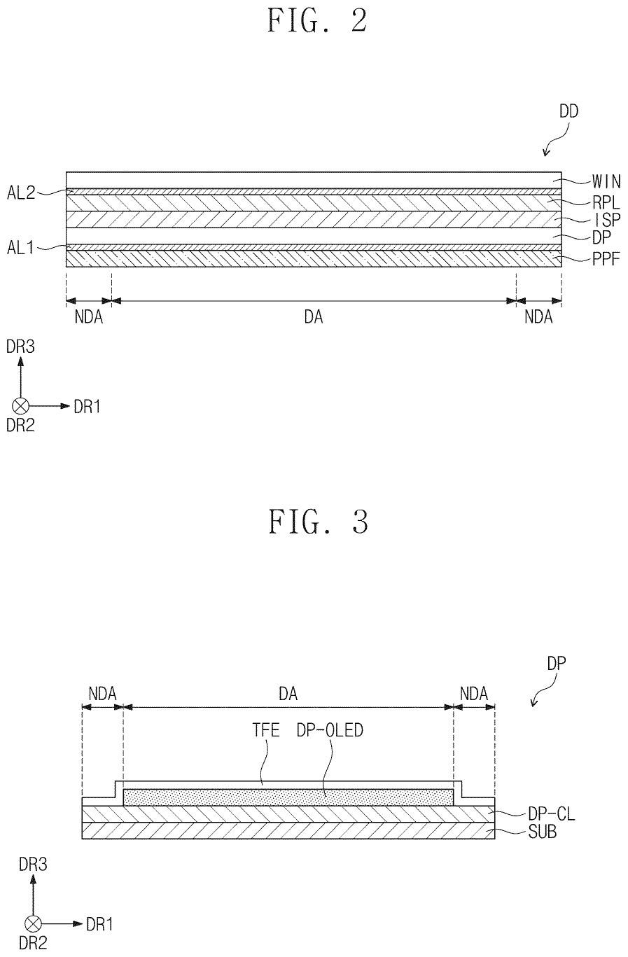

FIG. 3 is a view schematically illustrating a cross section of the display panel illustrated in FIG. 2.

Illustratively, FIG. 3 illustrates a cross section of the display panel DP when viewed in the second direction DR2.

Referring to FIG. 3, the display panel DP may include a substrate SUB, a circuit element layer DP-CL disposed on the substrate SUB, a display element layer DP-OLED disposed on the circuit element layer DP-CL, and a thin film encapsulation layer TFE disposed on the display element layer DP-OLED.

The substrate SUB may include the display area DA, and the non-display area NDA around the display area DA. The substrate SUB may include glass or a flexible plastic material, such as polyimide (PI). The display element layer DP-OLED may be disposed on the display area DA.

A plurality of pixels may be disposed in the circuit element layer DP-CL and the display element layer DP-OLED. Each of the pixels may include a transistor disposed at (e.g., in or on) the circuit element layer DP-CL, and a light emitting element disposed at (e.g., in or on) the display element layer DP-OLED and connected to the transistor.

The thin film encapsulation layer TFE may be disposed on the circuit element layer DP-CL to cover the display element layer DP-OLED. The thin film encapsulation layer TFE may protect the pixels from moisture, oxygen, and/or foreign substances.

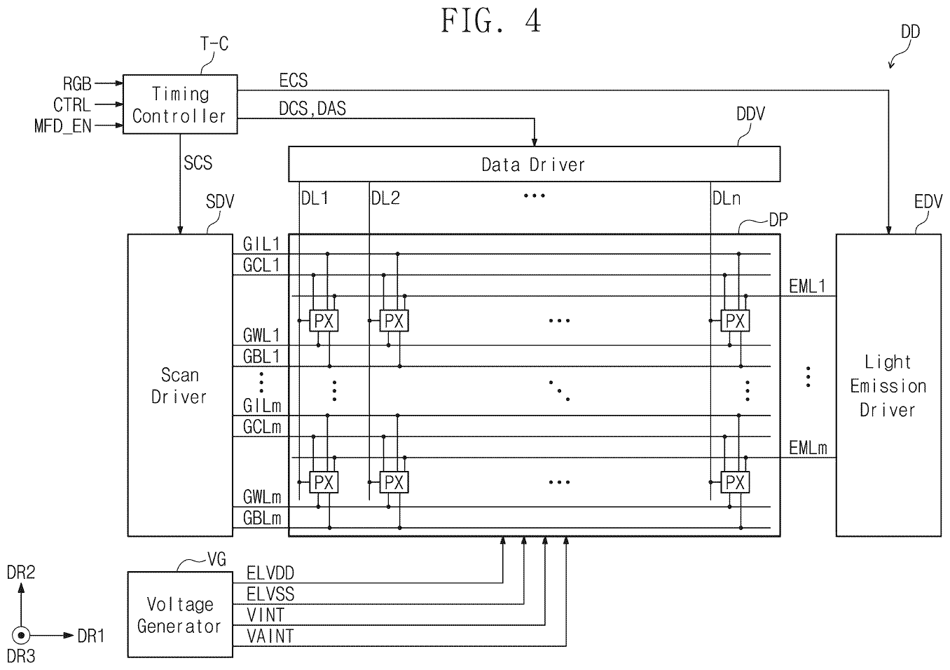

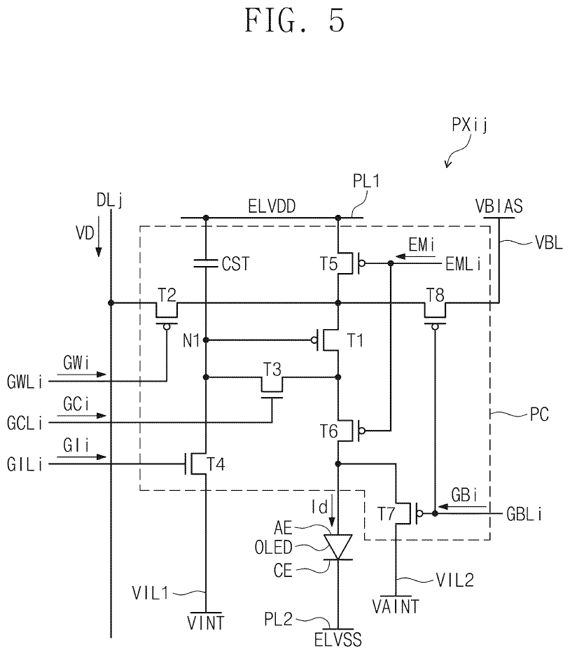

FIG. 4 is a block diagram of the display device illustrated in FIG. 1.

Referring to FIG. 4, the display device DD may include the display panel DP, a timing controller T-C, a scan driver SDV, a data driver DDV, a light emission driver EDV, and a voltage generator VG.

The display panel DP may include a plurality of scan lines GIL1 to GILm, GCL1 to GCLm, GWL1 to GWLm, and GBL1 to GBLm, a plurality of light emitting lines EML1 to EMLm, a plurality of data lines DL1 to DLn, and a plurality of pixels PX, where “m” and “n” are natural numbers.

The pixels PX may be electrically connected to the scan lines GIL1 to GILm, GCL1 to GCLm, GWL1 to GWLm, and GBL1 to GBLm, the light emitting lines EML1 to EMLm, and the data lines DL1 to DLn. Each of the pixels PX may be electrically connected to four corresponding scan lines, one corresponding data line, and one corresponding light emitting line.

The scan lines GIL1 to GILm, GCL1 to GCLm, GWL1 to GWLm, and GBL1 to GBLm may include a plurality of initialization scan lines GIL1 to GILm, a plurality of compensation scan lines GCL1 to GCLm, a plurality of writing scan lines GWL1 to GWLm, and a plurality of bias scan lines GBL1 to GBLm.

Each of the pixels PX may be connected to a corresponding one of the initialization scan lines GIL1 to GILm, a corresponding one of the compensation scan lines GCL1 to GCLm, a corresponding one of the writing scan lines GWL1 to GWLm, and a corresponding one of the bias scan lines GBL1 to GBLm.

The scan lines GIL1 to GILm, GCL1 to GCLm, GWL1 to GWLm, and GBL1 to GBLm may be connected to the scan driver SDV, may extend in the first direction DR1, and may be arranged along the second direction DR2. The light emitting lines EML1 to EMLm may be connected to the light emission driver EDV, may extend in the first direction DR1, and may be arranged along the second direction DR2. The data lines DL1 to DLn may be connected to the data driver DDV, may extend in the second direction DR2, and may be arranged along the first direction DR1.

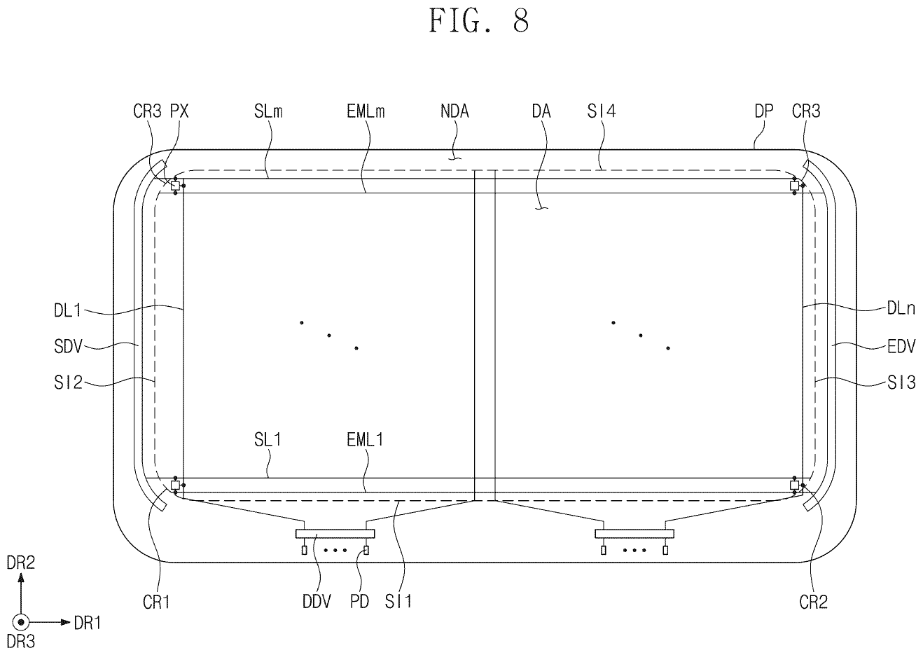

The scan driver SDV, the light emission driver EDV, and the data driver DDV may be substantially disposed on the display panel DP, and these components will be described in more detail below with reference to FIG. 8.

The timing controller T-C may receive an image signal RGB and a control signal CTRL. The timing controller T-C may generate an image data signal DAS obtained by converting a data format of the image signal RGB to satisfy interface specifications with the data driver DDV. The timing controller T-C may output a scan control signal SCS, a data control signal DCS, and a light emitting control signal ECS in response to the control signal CTRL.

The voltage generator VG may generate voltages used for operating the display panel DP. The voltage generator VG may generate a first driving voltage ELVDD, a second driving voltage ELVSS, a first initialization voltage VINT, and a second initialization voltage VAINT. The first driving voltage ELVDD, the second driving voltage ELVSS, the first initialization voltage VINT, and the second initialization voltage VAINT may be applied to the pixels PX.

The scan driver SDV may receive the scan control signal SCS from the timing controller T-C. The scan driver SDV may output the scan signals to the scan lines GIL1 to GILm, GCL1 to GCLm, GWL1 to GWLm, and GBL1 to GBLm in response to the scan control signal SCS. The scan signals may be applied to the pixels PX through the scan lines GIL1 to GILm, GCL1 to GCLm, GWL1 to GWLm, and GBL1 to GBLm.

The data driver DDV may receive the data control signal DCS and the image data signal DAS from the timing controller T-C. The data driver DDV may convert the image data signal DAS into data signals, and may output the converted data signals. The data signals may be defined as analog voltages corresponding to a grayscale level of the image data signal DAS. The data signals may be applied to the pixels PX through the data lines DL1 to DLn.

The light emission driver EDV may receive the light emitting control signal ECS from the timing controller T-C. The light emission driver EDV may output light emitting signals to the light emitting lines EML1 to EMLm in response to the light emitting control signal ECS. The light emitting signals may be applied to the pixels PX through the light emitting lines EML1 to EMLm.

The pixels PX may receive the data voltages in response to the scan signals. The pixels PX may display an image by emitting light having brightnesses corresponding to the data voltages in response to the light emitting signals.

FIG. 5 is a view illustrating an equivalent circuit of any one pixel illustrated in FIG. 4.

Illustratively, FIG. 5 illustrates a pixel PXij connected to a j^{th} data line DLj, i^{th} scan lines GWLi, GCLi, GILi, and GBLi, and an i^{th} light emitting line EMLi, where “i” and “j” are natural numbers.

Referring to FIG. 5, the pixel PXij may include a pixel circuit PC, and a light emitting element OLED connected to the pixel circuit PC. The pixel circuit PC may drive the light emitting element OLED.

The pixel circuit PC may include a plurality of transistors T1 to T8 and a capacitor CST. The transistors T1 to T8 and the capacitor CST may control an amount of a current flowing through the light emitting element OLED. The light emitting element OLED may generate light having a desired brightness (e.g., a predetermined brightness) according to the amount of the provided current.

The i^{th} writing scan line GWLi may receive an i^{th} writing scan signal GWi, and the i^{th} compensation scan line GCLi may receive an i^{th} compensation scan signal GCi. The i^{th} initialization scan line GILi may receive an i^{th} initialization scan signal GIi, and the i^{th} bias scan line GBLi may receive an i^{th} bias scan signal GBi. The i^{th} light emitting line EMLi may receive an i^{th} light emitting signal EMi.

The pixel PXij may be connected to the j^{th} data line DLj, the i^{th} writing scan line GWLi, the i^{th} compensation scan line GCLi, the i^{th} initialization scan line GILi, the i^{th} bias scan line GBLi, the i^{th} light emitting line EMLi, a first initialization line VIL1, a second initialization line VIL2, a bias line VBL, and first and second power lines PL1 and PL2.

The first initialization line VIL1 may receive the first initialization voltage VINT, and the second initialization line VIL2 may receive the second initialization voltage VAINT. The bias line VBL may receive a bias voltage VBIAS. The first power line PL1 may receive the first driving voltage ELVDD, and the second power line PL2 may receive the second driving voltage ELVSS.

Each of the transistors T1 to T8 may include a source electrode, a drain electrode, and a gate electrode. Hereinafter, with reference to FIG. 5, one of the source electrode or the drain electrode is defined as a first electrode, and the other thereof is defined as a second electrode, for convenience of illustration. Further, the gate electrode is defined as a control electrode.

The transistors T1 to T8 may include the first to eighth transistors T1 to T8. The first, second, and fifth to eighth transistors T1, T2, and T5 to T8 may be p-type metal oxide semiconductor (PMOS) transistors. The third and fourth transistors T3 and T4 may be n-type metal oxide semiconductor (NMOS) transistors.

The first transistor T1 may be defined as a driving transistor, and the second transistor T2 may be defined as a switching transistor. The third transistor T3 may be defined as a compensation transistor. The fourth transistor T4 and the seventh transistor T7 may be defined as initialization transistors. The fifth transistor T5 and the sixth transistor T6 may be defined as light emitting control transistors. The eighth transistor T8 may be defined as a bias transistor.

The light emitting element OLED may be defined as an organic light emitting element. The light emitting element OLED may include an anode AE and a cathode CE. The anode AE may receive the first driving voltage ELVDD through the fifth, first, and sixth transistors T5, T1, and T6. The first driving voltage ELVDD may be applied to the pixel circuit PC through the first power line PL1.

The cathode CE may receive the second driving voltage ELVSS having a lower level than that of the first driving voltage ELVDD. The second driving voltage ELVSS may be applied to the pixel circuit PC through the second power line PL2.

The first transistor T1 may be disposed between the fifth transistor T5 and the sixth transistor T6, and connected to the fifth transistor T5 and the sixth transistor T6. The first transistor T1 may be connected to the first power line PL1 through the fifth transistor T5, and may be connected to the anode AE through the sixth transistor T6.

The first transistor T1 may include a first electrode connected to the first power line PL1 through the fifth transistor T5, a second electrode connected to the anode AE through the sixth transistor T6, and a control electrode connected to a first node N1.

The first electrode of the first transistor T1 may be connected to the fifth transistor T5, and the second electrode of the first transistor T1 may be connected to the sixth transistor T6. The first transistor T1 may control the amount of the current flowing through the light emitting element OLED according to a voltage of the first node N1 applied to the control electrode of the first transistor T1.

The second transistor T2 may be disposed between the first transistor T1 and the j^{th} data line DLj, and connected to the first transistor T1 and the j^{th} data line DLj. The second transistor T2 may include a first electrode connected to the j^{th} data line DLj, a second electrode connected to the first electrode of the first transistor T1, and a control electrode connected to the i^{th} writing scan line GWLi.

The second transistor T2 may be turned on by the i^{th} writing scan signal GWi applied through the i^{th} writing scan line GWLi, and electrically connect the j^{th} data line DLj and the first electrode of the first transistor T1 to each other. The second transistor T2 may perform a switching operation of providing a data voltage VD (e.g., corresponding to the above-described data signal) applied through the j^{th} data line DLj to the first electrode of the first transistor T1.

The third transistor T3 may be connected to the second electrode of the first transistor T1 and the first node N1. The third transistor T3 may include a first electrode connected to the second electrode of the first transistor T1, a second electrode connected to the first node N1, and a control electrode connected to the i^{th} compensation scan line GCLi.

The third transistor T3 may be turned on by the i^{th} compensation scan signal GCi applied through the i^{th} compensation scan line GCLi, and electrically connect the second electrode of the first transistor T1 and the control electrode of the first transistor T1 to each other. When the third transistor T3 is turned on, the first transistor T1 and the third transistor T3 may be diode-connected to each other. In other words, the first transistor T1 may be diode-connected by the third transistor T3.

The fourth transistor T4 may be connected to the first node N1. The fourth transistor T4 may include a first electrode connected to the first node N1, a second electrode connected to the first initialization line VIL1, and a control electrode connected to the i^{th} initialization scan line GILi. The fourth transistor T4 may be turned on by the i^{th} initialization scan signal GIi applied through the i^{th} initialization scan line GILi, and provide the first initialization voltage VINT applied through the first initialization line VIL1 to the first node N1.

The fifth transistor T5 may include a first electrode connected to the first power line PL1, a second electrode connected to the first electrode of the first transistor T1, and a control electrode connected to the i^{th} light emitting line EMLi.

The sixth transistor T6 may include a first electrode connected to the second electrode of the first transistor T1, a second electrode connected to the anode AE, and a control electrode connected to the i^{th} light emitting line EMLi.

The fifth transistor T5 and the sixth transistor T6 may be turned on by the i^{th} light emitting signal EMi applied through the i^{th} light emitting line EMLi. The first driving voltage ELVDD may be provided to the light emitting element OLED by the turned-on fifth transistor T5 and the turned-on sixth transistor T6, so that a driving current may flow in the light emitting element OLED. Thus, the light emitting element OLED may emit light.

The seventh transistor T7 may include a first electrode connected to the anode AE, a second electrode connected to the second initialization line VIL2, and a control electrode connected to the i^{th} bias scan line GBLi. The seventh transistor T7 may be turned on by the i^{th} bias scan signal GBi applied through the i^{th} bias scan line GBLi, and provide the second initialization voltage VAINT received through the second initialization line VIL2 to the anode AE of the light emitting element OLED.

In an embodiment of the present disclosure, the second initialization voltage VAINT may have a different level from that of the first initialization voltage VINT, but the present disclosure is not limited thereto, and the second initialization voltage VAINT may have the same level as that of the first initialization voltage VINT.

The seventh transistor T7 may improve a black expression capability of the pixel PXij. When the seventh transistor T7 is turned on, a parasitic capacitor of the light emitting element OLED may be discharged. Thus, when a black brightness is implemented, the light emitting element OLED may not emit light due to a leakage current of the first transistor T1, and accordingly, the black expression capability may be improved.

The capacitor CST may include a first electrode connected to the first power line PL1, and a second electrode connected to the first node N1. When the fifth transistor T5 and the sixth transistor T6 are turned on, the amount of the current flowing through the first transistor T1 may be determined according to a voltage stored in the capacitor CST.

The eighth transistor T8 may include a first electrode connected to the bias line VBL, a second electrode connected to the first electrode of the first transistor T1, and a control electrode connected to the i^{th} bias scan line GBLi.

The eighth transistor T8 may be turned on by the i^{th} bias scan signal GBi, and provide the bias voltage VBIAS applied through the bias line VBL to the first electrode of the first transistor T1.

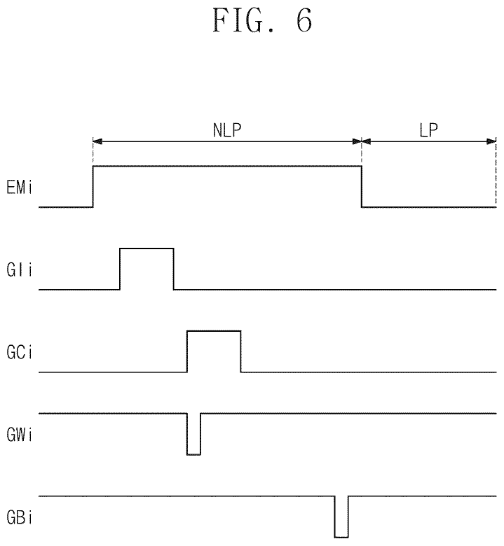

FIG. 6 is a timing diagram of scan signals and light emitting signals for an operation of the pixel illustrated in FIG. 5.

Referring to FIGS. 5 and 6, the i^{th} light emitting signal EMi may have a high level during a non-light emitting period NLP, and may have a low level during a light emitting period LP.

An activation period of each of the i^{th} writing scan signal GWi and the i^{th} bias scan signal GBi may be defined as a low level of each of the i^{th} writing scan signal GWi and the i^{th} bias scan signal GBi.

An activation period of each of the i^{th} compensation scan signal GCi and the i^{th} initialization scan signal GIi may be defined as a high level of each of the i^{th} compensation scan signal GCi and the i^{th} initialization scan signal GIi.

After the i^{th} initialization scan signal GIi is activated, the i^{th} compensation scan signal GCi and the i^{th} writing scan signal GWi may be activated. Thereafter, the i^{th} bias scan signal GBi may be activated.

During the non-light emitting period NLP, the i^{th} initialization scan signal GIi, the i^{th} compensation scan signal GCi, the i^{th} writing scan signal GWi, and the i^{th} bias scan signal GBi that are activated may be applied to the pixel PXij.

The i^{th} initialization scan signal GIi may be applied to the fourth transistor T4 to turn on the fourth transistor T4. The first initialization voltage VINT may be provided to the first node N1 through the fourth transistor T4. Thus, the first initialization voltage VINT may be applied to the control electrode of the first transistor T1, and the first transistor T1 may be initialized by the first initialization voltage VINT. This operation may be defined as an initialization operation.

The i^{th} writing scan signal GWi may be applied to the second transistor T2 to turn on the second transistor T2. Further, the i^{th} compensation scan signal GCi may be applied to the third transistor T3 to turn on the third transistor T3.

The first transistor T1 and the third transistor T3 may be diode-connected to each other. In this case, a compensation voltage (e.g., Vd-Vth) obtained by subtracting the data voltage VD supplied through the j^{th} data line DLj by a threshold voltage Vth of the first transistor T1 may be applied to the control electrode of the first transistor T1. This operation may be defined as a writing operation (e.g., a programming operation) and a compensation operation.

The first driving voltage ELVDD and the compensation voltage (e.g., Vd-Vth) may be applied to the first electrode and the second electrode of the capacitor CST. A charge corresponding to a difference between a voltage of the first electrode of the capacitor CST and a voltage of the second electrode of the capacitor CST may be stored in the capacitor CST.

Thereafter, the i^{th} bias scan signal GBi may be applied to the seventh and eighth transistors T7 and T8 to turn on the seventh and eighth transistors T7 and T8. The second initialization voltage VAINT may be provided to the anode AE through the seventh transistor T7, so that the anode AE may be initialized through the second initialization voltage VAINT. The bias voltage VBIAS may be applied to the first electrode of the first transistor T1 through the eighth transistor T8.

Thereafter, during the light emitting period LP, the i^{th} light emitting signal EMi may be applied to the fifth transistor T5 and the sixth transistor T6 through the i^{th} light emitting line EMLi to turn on the fifth transistor T5 and the sixth transistor T6. In this case, a driving current Id corresponding to a difference between the voltage of the control electrode of the first transistor T1 and the first driving voltage ELVDD may be generated. The driving current Id may be provided to the light emitting element OLED through the sixth transistor T6, so that the light emitting element OLED may emit light.

During the light emitting period LP, a gate-source voltage (e.g., Vgs) of the first transistor T1 by the capacitor CST may be defined as Vgs=ELVDD−(Vd-Vth). A current and voltage relational expression of the first transistor T1 may be generally defined as Id=(1/2)μCox(W/L)(Vgs-Vth)².

When Vgs is substituted into the current and voltage relational expression, the threshold voltage Vth may be removed, and the driving current Id may be proportional to a square value (ELVDD-Vd)² of a value obtained by subtracting the data voltage VD from the first driving voltage ELVDD. Thus, the driving current Id may be determined regardless of the threshold voltage Vth of the first transistor T1. This operation may be defined as a threshold voltage compensation operation.

The bias voltage VBIAS may be applied to the first electrode of the first transistor T1 through the eighth transistor T8 after the threshold voltage of the first transistor T1 is compensated for and before the light emitting element OLED emits light. Movement of a hysteresis curve of the first transistor T1 may be suppressed by the bias voltage VBIAS. This operation may be defined as a bias operation.

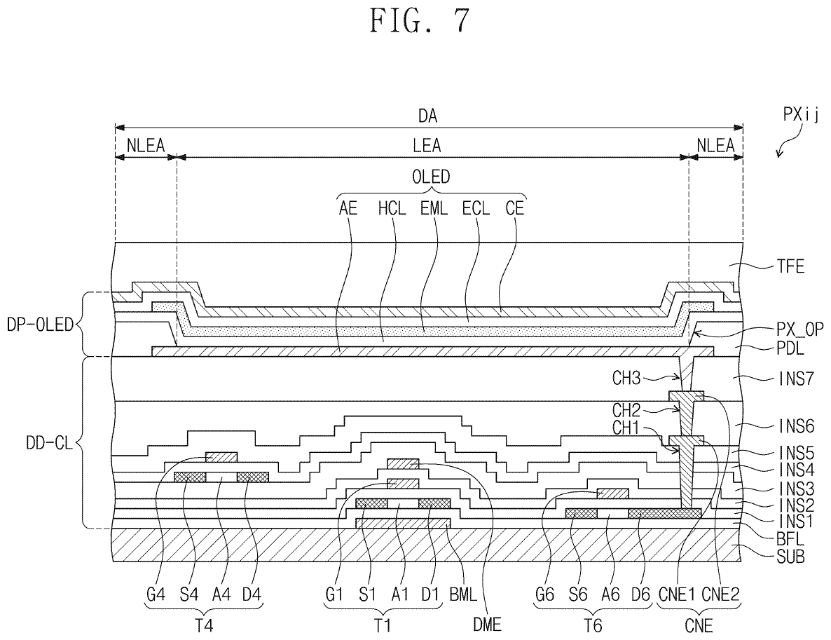

FIG. 7 is a view schematically illustrating a cross section of the light emitting element, the first transistor, the fourth transistor, and the sixth transistor of the pixel illustrated in FIG. 5.

Referring to FIG. 7, the light emitting element OLED may include a first electrode AE, a second electrode CE, a hole control layer HCL, an electron control layer ECL, and a light emitting layer EML. The first electrode AE may be the anode AE illustrated in FIG. 5, and the second electrode CE may be the cathode CE illustrated in FIG. 5. The second electrode CE may be disposed above the first electrode AE, and the hole control layer HCL, the electron control layer ECL, and the light emitting layer EML may be disposed between the first electrode AE and the second electrode CE.

The first, fourth, and sixth transistors T1, T4, and T6, and the light emitting element OLED may be disposed on the substrate SUB. The display area DA may include a light emitting area LEA corresponding to the pixel PXij, and a non-light emitting area NLEA adjacent to the light emitting area LEA. The light emitting element OLED may be disposed in the light emitting area LEA.

A lower metal layer BML may be disposed on the substrate SUB. The lower metal layer BML may overlap with the first transistor T1. A constant or substantially constant voltage may be applied to the lower metal layer BML. When the constant voltage is applied to the lower metal layer BML, the threshold voltage Vth of the first transistor T1 disposed on the lower metal layer BML may be maintained without changing.

The lower metal layer BML may block light input to the first transistor T1 from a lower side of the lower metal layer BML. The lower metal layer BML may include a reflective metal. The lower metal layer BML may be omitted as needed or desired.

A buffer layer BFL may be disposed on the substrate SUB, and the buffer layer BFL may be an inorganic layer. The buffer layer BFL may cover the lower metal layer BML. Semiconductor layers S1, A1, and D1 of the first transistor T1 and semiconductor layers S6, A6, and D6 of the sixth transistor T6 may be disposed on the buffer layer BFL. The semiconductor layers S1, A1, D1, S6, A6, and D6 may include polysilicon. However, the present disclosure is not limited thereto, and the semiconductor layers S1, A1, D1, S6, A6, and D6 may include amorphous silicon.

The semiconductor layers S1, A1, D1, S6, A6, and D6 may be doped with N-type dopants or P-type dopants. The semiconductor layers S1, A1, D1, S6, A6, and D6 may include a high doped area and a low doped area. The high doped area may have a conductivity that is greater than a conductivity of the low doped area, and may substantially serve as source electrodes and drain electrodes of the first and sixth transistors T1 and T6. The low doped area may substantially correspond to active areas (e.g., channels) of the first and sixth transistors T1 and T6.

The first source area S1, the first channel area A1, and the first drain area D1 of the first transistor T1 may be formed from the semiconductor layers S1, A1, and D1. The sixth source area S6, the sixth channel area A6, and the sixth drain area D6 of the sixth transistor T6 may be formed from the semiconductor layers S6, A6, and D6. The first channel area A1 may be disposed between the first source area S1 and the first drain area D1. The sixth channel area A6 may be disposed between the sixth source area S6 and the sixth drain area D6.

A first insulating layer INS1 may be disposed on the buffer layer BFL to cover the semiconductor layers S1, A1, D1, S6, A6, and D6. A first gate electrode G1 (e.g., a control electrode) of the first transistor T1 and a sixth gate electrode G6 (e.g., a control electrode) of the sixth transistors T6 may be disposed on the first insulating layer INS1. When viewed on a plane, the first gate electrode G1 may overlap with the first channel area A1, and the sixth gate electrode G6 may overlap with the sixth channel area A6.

Structures of a source area, a channel area, a drain area, and a gate electrode of each of the second, fifth, and seventh transistors T2, T5, and T7 may be the same or substantially the same as those of the first and sixth transistors T1 and T6.

A second insulating layer INS2 may be disposed on the first insulating layer INS1 to cover the first and sixth gate electrodes G1 and G6. A dummy electrode DME may be disposed on the second insulating layer INS2. The dummy electrode DME may be disposed on the first gate electrode G1, and may overlap with the first gate electrode G1 when viewed on a plane. The dummy electrode DME may form the capacitor CST together with the first gate electrode G1.

A third insulating layer INS3 may be disposed on the second insulating layer INS2 to cover the dummy electrode DME. Semiconductor layers S4, A4, and D4 of the fourth transistor T4 may be disposed on the third insulating layer INS3. The semiconductor layers S4, A4, and D4 may include an oxide semiconductor formed of a metal oxide. The oxide semiconductor may include a crystalline or amorphous oxide semiconductor.

The semiconductor layers S4, A4, and D4 may include a plurality of areas that are divided depending on whether or not the metal oxide is reduced. An area (hereinafter, referred to as a reduced area) in which the metal oxide is reduced has a higher conductivity than that of an area (hereinafter, referred to as a non-reduced area) in which the metal oxide is not reduced. The reduced area may substantially serve as a source electrode or a drain electrode of the fourth transistor T4. The non-reduced area may substantially correspond to an active area (e.g., a channel) of the fourth transistor T4.

The fourth source area S4, the fourth channel area A4, and the fourth drain area D4 of the fourth transistor T4 may be formed from the semiconductor layers S4, A4, and D4. The fourth channel area A4 may be disposed between the fourth source area S4 and the fourth drain area D4.

A fourth insulating layer INS4 may be disposed on the third insulating layer INS3 to cover the semiconductor layers S4, A4, and D4. A fourth gate electrode G4 of the fourth transistor T4 may be disposed on the fourth insulating layer INS4. When viewed on a plane, the fourth gate electrode G4 may overlap with the fourth channel area A4.

A fifth insulating layer INS5 may be disposed on the fourth insulating layer INS4 to cover the fourth gate electrode G4. Structures of a source area, a channel area, a drain area, and a gate electrode of the third transistor T3 may be the same or substantially the same as those of the fourth transistor T4.

The buffer layer BFL and the first to fifth insulating layers INS1 to INS5 may include inorganic layers. Illustratively, the buffer layer BFL, the first insulating layer INS1, and the fourth insulating layer INS4 may include a silicon oxide layer, and the second insulating layer INS2 may include a silicon nitride layer.

The third and fifth insulating layers INS3 and INS5 may include a plurality of inorganic insulating layers including different materials from each other and laminated on each other. For example, the third insulating layer INS3 may include a silicon nitride layer and a silicon oxide layer that are sequentially laminated, and the fifth insulating layer INS5 may include a silicon oxide layer and a silicon nitride layer that are sequentially laminated. A thickness of each of the third and fifth insulating layers INS3 and INS5 may be greater than a thickness of each of the buffer layer BFL and the first, second, and fourth insulating layers INS1, INS2, and INS4.

A connection electrode CNE may be disposed between the sixth transistor T6 and the light emitting element OLED. The connection electrode CNE may electrically connect the sixth transistor T6 and the light emitting element OLED to each other. The connection electrode CNE may include a first connection electrode CNE1, and a second connection electrode CNE2 disposed on the first connection electrode CNE1.

The first connection electrode CNE1 may be disposed on the fifth insulating layer INS5, and may be connected to the sixth drain area D6 through a first contact hole CH1 defined by (e.g., penetrating) the first to fifth insulating layers INS1 to INS5. A sixth insulating layer INS6 may be disposed on the fifth insulating layer INS5 to cover the first connection electrode CNE1.

The second connection electrode CNE2 may be disposed on the sixth insulating layer INS6. The second connection electrode CNE2 may be connected to the first connection electrode CNE1 through a second contact hole CH2 defined by (e.g., penetrating) the sixth insulating layer INS6.

A seventh insulating layer INS7 may be disposed on the sixth insulating layer INS6 to cover the second connection electrode CNE2. The sixth and seventh insulating layers INS6 and INS7 may include inorganic layers or organic layers.

The first electrode AE may be disposed on the seventh insulating layer INS7. The first electrode AE may be electrically connected to the second connection electrode CNE2 through a third contact hole CH3 defined by (e.g., penetrating) the seventh insulating layer INS7.

A pixel defining film PDL, through which a portion (e.g., a predetermined portion) of the first electrode AE is exposed, may be disposed on the first electrode AE and the seventh insulating layer INS7. An opening PX_OP, through which the portion of the first electrode AE is exposed, may be defined in the pixel defining film PDL.

The hole control layer HCL may be disposed on the first electrode AE and the pixel defining film PDL. The hole control layer HCL may be commonly disposed in the light emitting area LEA and the non-light emitting area NLEA. The hole control layer HCL may include a hole transport layer and/or a hole injection layer.

The light emitting layer EML may be disposed on the hole control layer HCL. The light emitting layer EML may be disposed in an area corresponding to the opening PX_OP. The light emitting layer EML may include an organic material and/or an inorganic material. The light emitting layer EML may generate light having any one of a red color, a green color, and/or a blue color.

The electron control layer ECL may be disposed on the light emitting layer EML and the hole control layer HCL. The electron control layer ECL may be commonly disposed in the light emitting area LEA and the non-light emitting area NLEA. The electron control layer ECL may include an electron transport layer and/or an electron injection layer.

The second electrode CE may be disposed on the electron control layer ECL. The second electrode CE may be commonly disposed in the pixels PX. In other words, the second electrode CE may be commonly disposed on the light emitting layers EML of the pixels PX.

The layers from the buffer layer BFL to the seventh insulating layer INS7 may be defined as the circuit element layer DP-CL. The layer, at (e.g., in or on) which the light emitting element OLED is disposed, may be defined as the display element layer DP-OLED.

The thin film encapsulation layer TFE may be disposed on the light emitting element OLED. The thin film encapsulation layer TFE may include an inorganic layer, an organic layer, and an inorganic layer, which are sequentially laminated. The inorganic layers may include inorganic materials, and may protect the pixels from moisture/oxygen. The organic layer may include an organic material, and may protect the pixels PX from foreign substances, such as dust particles.

The first driving voltage ELVDD may be applied to the first electrode AE, and the second driving voltage ELVSS may be applied to the second electrode CE. Holes and electrons injected into the light emitting layer EML are combined with each other to form excitons, and as the excitons transition to a ground state, the light emitting element OLED may emit light. The light emitting element OLED may emit light to display an image.

FIG. 8 is a plan view of the display panel illustrated in FIG. 4.

FIG. 4 is a view mainly illustrating some functional blocks of the display device DD, and FIG. 8 is a view mainly illustrating a schematic planar structure of the display panel DP.

Referring to FIG. 8, the display device DD may include the display panel DP, the scan driver SDV, the plurality of data drivers DDV, the light emission driver EDV, and a plurality of pads PD. The display panel DP may have a rounded corner quadrangular shape to correspond to the shape of the display device DD.

An edge of the display panel DP may have long sides extending in the first direction DR1, and short sides extending in the second direction DR2. The long sides and the short sides of the display panel DP may correspond to the sides of a quadrangular shape. The edge of the display panel DP may include rounded corners connecting the long sides and the short sides of the display panel DP to each other. Each of the rounded corners may connect two adjacent ones of the long sides and the short sides to each other.

The display panel DP may include the display area DA, and the non-display area NDA disposed around the display area DA. For example, the non-display area NDA may surround (e.g., around a periphery of) the display area DA. The display area DA may have a rounded corner quadrangular shape to correspond to the shape of the display panel DP.

In the rounded corner quadrangular shape, the display area DA may include first to fourth sides SI1 to SI4, and first to third rounded corners CR1 to CR3. The first to fourth sides SI1 to SI4 may define four sides of the quadrangle. The first to third rounded corners CR1 to CR3 may define four rounded corners of the quadrangle.

The first side SI1 and the fourth side SI4 may extend in the first direction DR1 in parallel with each other, and may be opposite to each other in the second direction DR2. The second side SI2 and the third side SI3 may extend in the second direction DR2 in parallel with each other, and may be opposite to each other in the first direction DR1. The first side SI1 and the fourth side SI4 may extend longer than the second side SI2 and the third side SI3. The first side SI1 and the fourth side SI4 may be defined as the long sides, and the second side SI2 and third side SI3 may be defined as the short sides.

The second side SI2 and the third side SI3 may be adjacent to both ends (e.g., opposite ends) of the first side SI1, and may extend in the second direction DR2. The second side SI2 may be disposed adjacent to one end of the first side SI1, and may extend in the second direction DR2. The third side SI3 may be disposed adjacent to another end of the first side SI1, and may extend in the second direction DR2. One end of the second side SI2 may be adjacent to the one end of the first side SI1, and one end of the third side SI3 may be adjacent to the other end of the first side SI1.

The fourth side SI4 may be adjacent to the other end of the second side SI2 and the other end of the third side SI3, and may extend in the first direction DR1. One end of the fourth side SI4 may be adjacent to the other end of the second side SI2, and the other end of the fourth side SI4 may be adjacent to the other end of the third side SI3.

The one end and the other end of the first side SI1 may be defined as both ends (e.g., opposite ends) of the first side SI1, which are opposite to each other in the first direction DR1. The one end and the other end of the second side SI2 may be defined as both ends of the second side SI2, which are opposite to each other in the second direction DR2. The one end and the other end of the third side SI3 may be defined as both ends of the third side SI3, which are opposite to each other in the second direction DR2. The one end and the other end of the fourth side SI4 may be defined as both ends of the fourth side SI4, which are opposite to each other in the first direction DR1.

In the first direction DR1, a distance between the second side SI2 and the third side SI3 may be greater than a length of the first side SI1 and a length of the fourth side SI4. In the second direction DR2, a distance between the first side SI1 and the fourth side SI4 may be greater than a length of the second side SI2 and a length of the third side SI3.

When viewed in the second direction DR2, the first side SI1 and the fourth side SI4 may be disposed between the second side SI2 and the third side SI3. When viewed in the first direction DR1, the second side SI2 and the third side SI3 may be disposed between the first side SI1 and the fourth side SI4.

The first rounded corner CR1 may connect the first side SI1 and the second side SI2 to each other. For example, the first rounded corner CR1 may connect the one end of the first side SI1 and the one end of the second side SI2, which are adjacent to each other, to each other. The first rounded corner CR1 may have a curved shape that is convexly bent toward the non-display area NDA.

The second rounded corner CR2 may connect the first side SI1 and the third side SI3 to each other. For example, the second rounded corner CR2 may connect the other end of the first side SI1 and the one end of the third side SI3, which are adjacent to each other, to each other. The second rounded corner CR2 may have a curved shape that is convexly bent toward the non-display area NDA.

The two third rounded corners CR3 may connect both ends (e.g., opposite ends) of the fourth side SI4 to the other end of the second side SI2 and the other end of the third side SI3. One third rounded corner CR3 may connect the other end of the second side SI2 and the one end of the fourth side SI4, which are adjacent to each other, to each other. The other third rounded corner CR3 may connect the other end of the third side SI3 and the other end of the fourth side SI4, which are adjacent to each other, to each other. The third rounded corners CR3 may have a curved shape that is convexly bent toward the non-display area NDA.

The first rounded corner CR1 and the second rounded corner CR2 may have shapes that are symmetrical to or substantially symmetrical to each other in the first direction DR1. The third rounded corners CR3 may have shapes that are symmetrical to or substantially symmetrical to each other in the first direction DR1. The first and seconded rounded corners CR1 and CR2 and the third rounded corners CR3 may have shapes that are symmetrical to or substantially symmetrical to one another in the second direction DR2.

The display panel DP may include the plurality of pixels PX, the plurality of scan lines SL1 to SLm, the plurality of data lines DL1 to DLn, and the plurality of light emitting lines EML1 to EMLm. The pixels PX may be disposed inside the display area DA. The pixels PX may be connected to the scan lines SL1 to SLm, the data lines DL1 to DLn, and the light emitting lines EML1 to EMLm.

The scan lines SL1 to SLm may include the scan lines GIL1 to GILm, GCL1 to GCLm, GWL1 to GWLm, and GBL1 to GBLm described above with reference to FIG. 4. For example, among the scan lines SL1 to SLm, the i^{th} scan line may include the i^{th} writing scan line GWLi, the i^{th} compensation scan line GCLi, the i^{th} initialization scan line GILi, and the i^{th} bias scan line GBLi. Thus, the above-described scan signals may be applied to the pixels PX through the scan lines SL1 to SLm.

The data lines DL1 to DLn and the light emitting lines EML1 to EMLm may be the same as the data lines DL1 to DLn and the light emitting lines EML1 to EMLm described above with reference to FIG. 4.

The scan driver SDV and the light emission driver EDV may be disposed in the non-display area NDA adjacent to both sides (e.g., opposite sides) of the display panel DP, which are opposite to each other in the first direction DR1. The scan driver SDV may be adjacent to the second side SI2, the first rounded corner CR1, and the third rounded corner CR3 connected to the second side SI2. The light emission driver EDV may be adjacent to the third side SI3, the second rounded corner CR2, and the third rounded corner CR3 connected to the third side SI3.

A portion of the scan driver SDV adjacent to the first rounded corner CR1 and a portion of the scan driver SDV adjacent to the third rounded corner CR3 connected to the second side SI2 may have a curved shape. A portion of the light emission driver EDV adjacent to the second rounded corner CR2 and a portion of the light emission driver EDV adjacent to the third rounded corner CR3 connected to the third side SI3 may have a curved shape.

The data driver DDV described above with reference to FIG. 4 may be substantially provided as a plurality of data drivers DDV in the display panel DP as illustrated in FIG. 8. The data drivers DDV may be disposed in the non-display area NDA adjacent to one side from among both sides (e.g., opposite sides) of the display panel DP, which are opposite to each other in the second direction DR2. When viewed on a plane, the data drivers DDV may be adjacent to a lower end of the display panel DP. For example, the data drivers DDV may be adjacent to the first side SI1.

The scan lines SL1 to SLm may extend in the first direction DR1, and may be connected to the pixels PX and the scan driver SDV. The data lines DL1 to DLn may extend in the second direction DR2, and may be connected to the pixels PX and the data drivers DDV. The light emitting lines EML1 to EMLm may extend in the first direction DR1, and may be connected to the pixels PX and the light emission driver EDV.

The data drivers DDV may be spaced apart from each other in the first direction DR1. A number (e.g., a predetermined number) of data lines may be connected to each of the data drivers DDV. As an example, two data drivers DDV are illustrated, but the number of data drivers DDV is not limited thereto. For example, as a left-right area of the display panel DP is increased, the number of data drivers DDV may also be increased.

The pads PD may be disposed on the non-display area NDA adjacent to a lower end of the display panel DP, and may be closer to the lower end of the display panel DP than the data drivers DDV. The data drivers DDV may be connected to the pads PD. The data lines DL1 to DLn may be connected to the data drivers DDV, and the data drivers DDV may be connected to the pads PD corresponding to the data lines DL1 to DLn.

The timing controller T-C and the voltage generator VG described above with reference to FIG. 4 may be mounted on a printed circuit board, and may be connected to the pads PD through the printed circuit board.

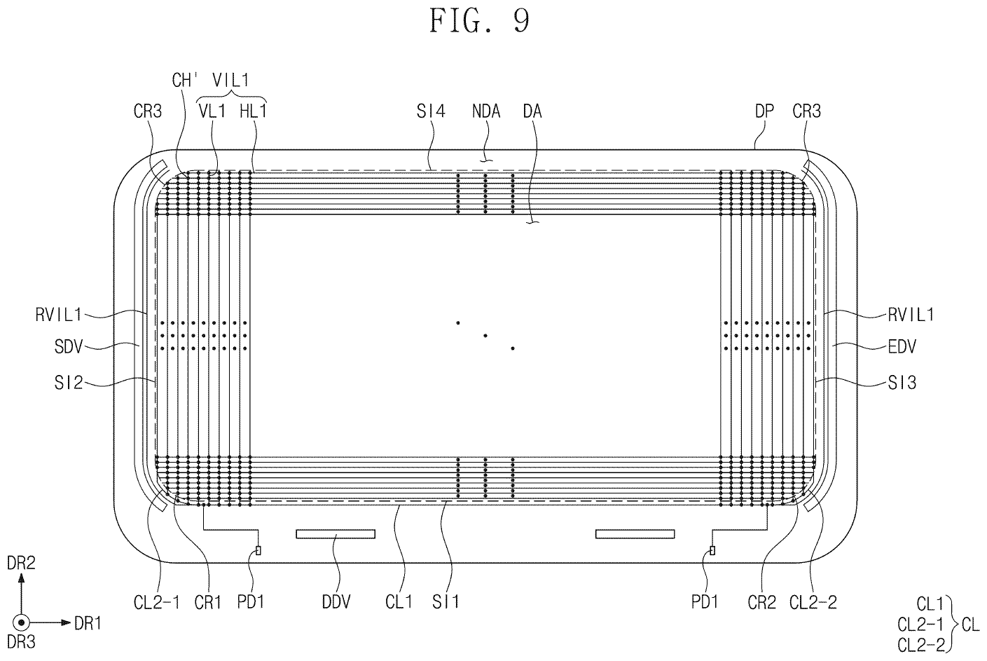

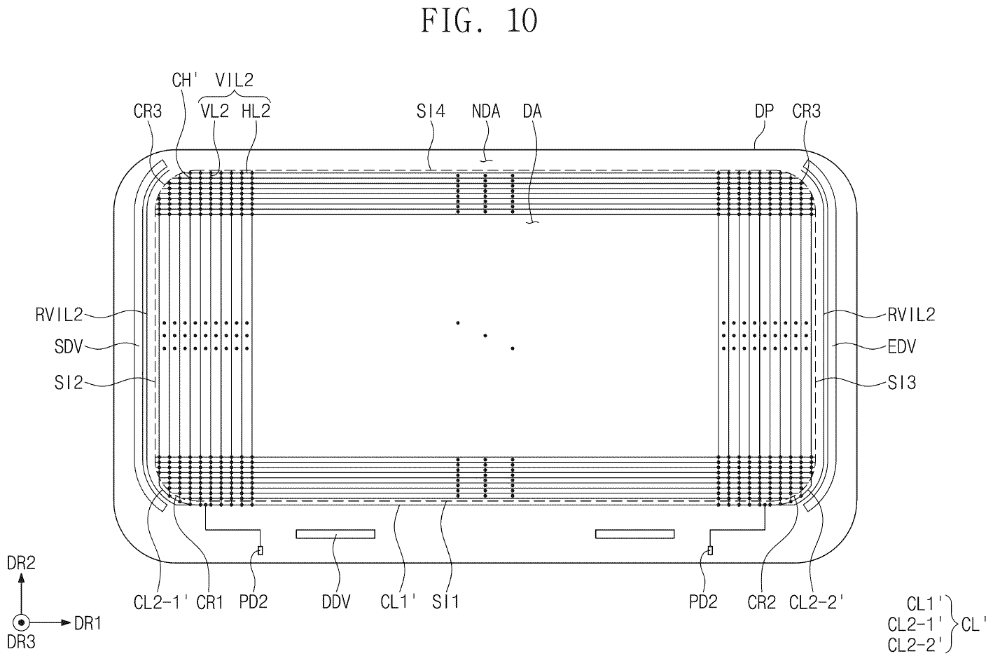

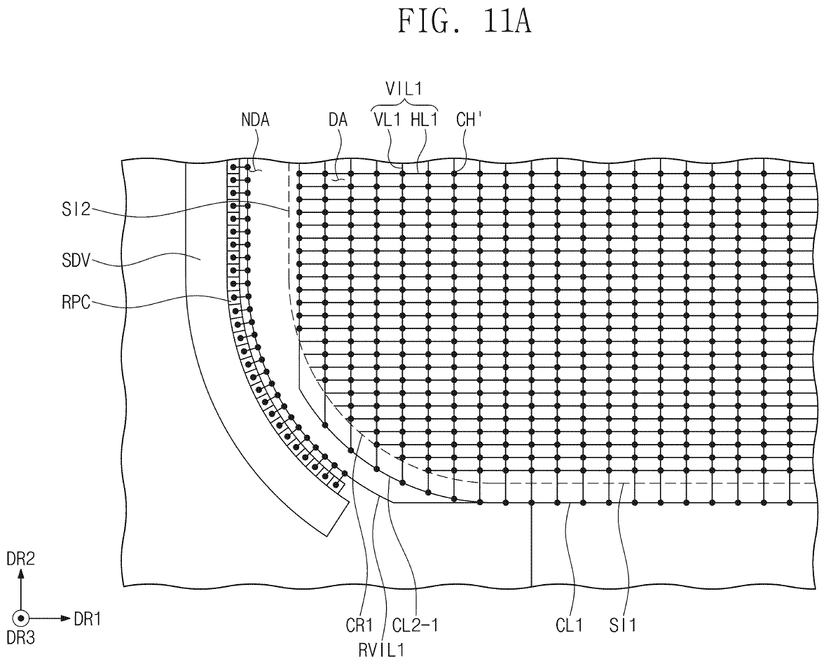

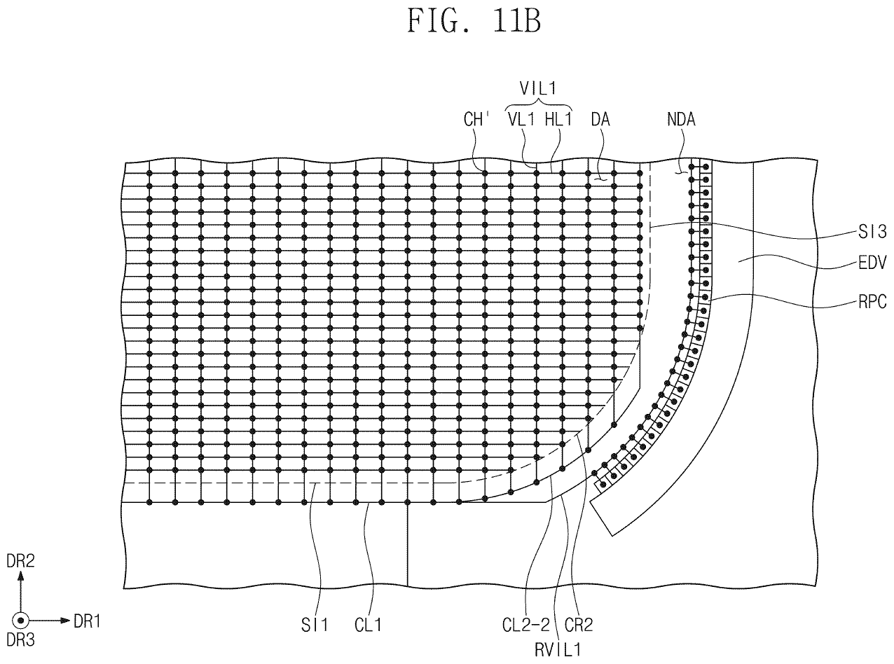

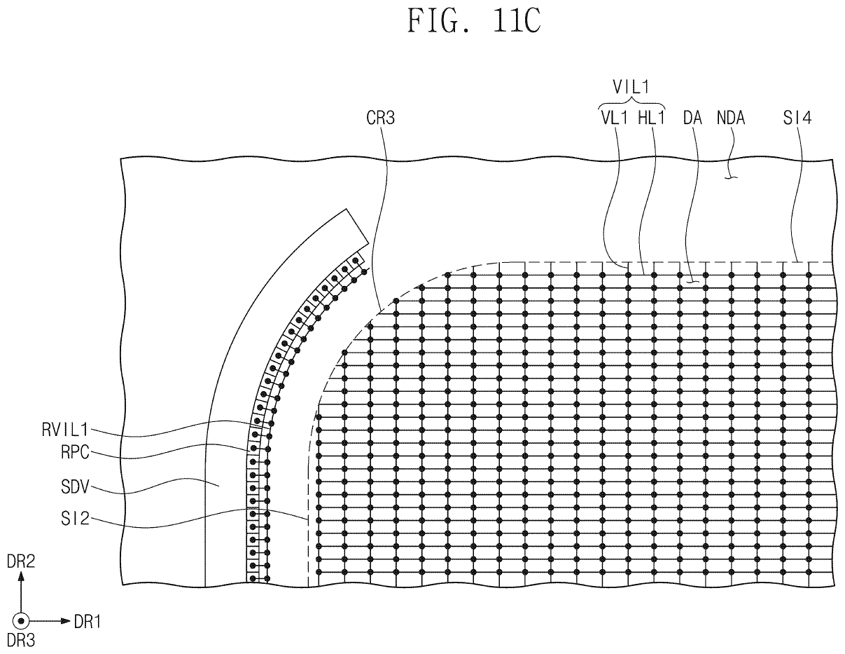

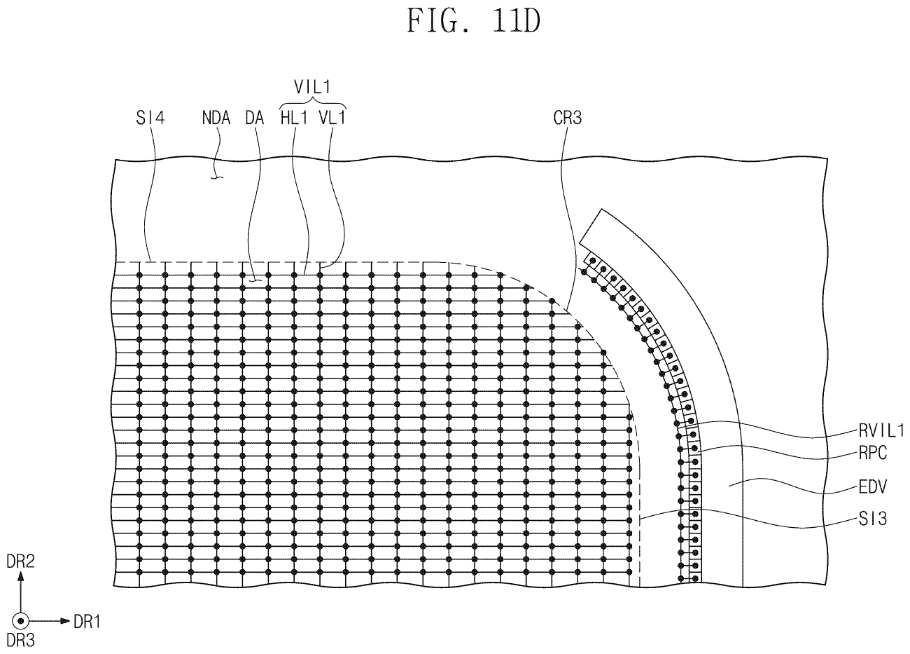

FIG. 9 is a view separately illustrating a configuration of a first initialization line disposed on the display panel illustrated in FIG. 8. FIG. 10 is a view separately illustrating a configuration of a second initialization line disposed on the display panel illustrated in FIG. 8. FIG. 11A is an enlarged view of a portion of the display panel adjacent to a first rounded corner illustrated in FIG. 9. FIG. 11B is an enlarged view of a portion of the display panel adjacent to a second rounded corner illustrated in FIG. 9. FIGS. 11C and 11D are enlarged views of portions of the display panel adjacent to third rounded corners illustrated in FIG. 9.

Illustratively, FIGS. 9 and 10 show the scan driver SDV, the data drivers DDV, and the light emission driver EDV, together with the first and second initialization lines VIL1 and VIL2.

Referring to FIGS. 9 and 10, the first initialization line VIL1 may include a plurality of first vertical initialization lines VL1 and a plurality of first horizontal initialization lines HL1. The second initialization line VIL2 may include a plurality of second vertical initialization lines VL2 and a plurality of second horizontal initialization lines HL2.

Each of the first and second initialization lines VIL1 and VIL2 may be defined as an initialization line. Further, the first and second vertical initialization lines VL1 and VL2 may be defined as vertical initialization lines, and the first and second horizontal initialization lines HL1 and HL2 may be defined as horizontal initialization lines.

The arrangement form of the second vertical initialization lines VL2 and the second horizontal initialization lines HL2 may be the same or substantially the same as the arrangement form of the first vertical initialization lines VL1 and the first horizontal initialization lines HL1. Thus, hereinafter, configurations of the first vertical initialization lines VL1 and the first horizontal initialization lines HL1 will be mainly described, and configurations of the second vertical initialization lines VL2 and the second horizontal initialization lines HL2 will be briefly described.

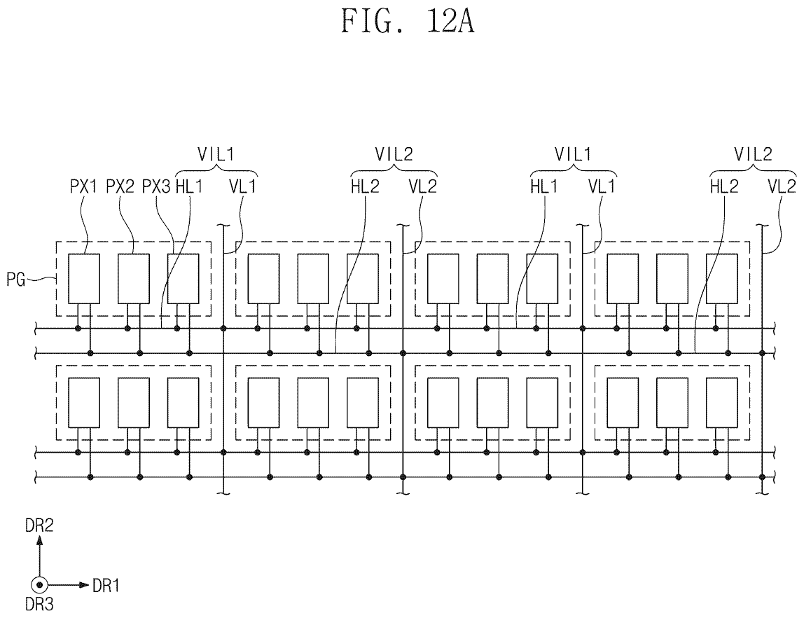

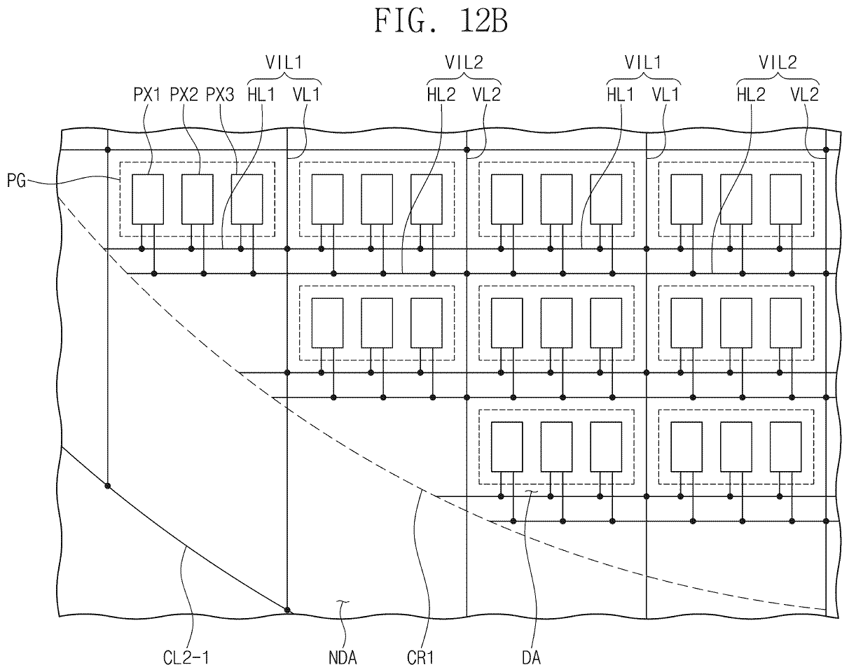

A structure in which the first vertical initialization lines VL1 and the first horizontal initialization lines HL1 and the second vertical initialization lines VL2 and the second horizontal initialization lines HL2 are connected to the pixels PX will be described in more detail below with reference to FIGS. 12A and 12B.

The display panel DP may include a common line CL connected to the first initialization line VIL1, and a common line CL′ connected to the second initialization line VIL2.

The common line CL may include a first common line CL1, a (2-1)^{th} common line CL2-1, and a (2-2)^{th} common line CL2-2. The common line CL′ may include a first common line CL1′, a (2-1)^{th} common line CL2-1′, and a (2-2)^{th} common line CL2-2′.

The display panel DP may include first repair initialization lines RVIL1 extending from both sides (e.g., opposite sides) of the first common line CL1, which are opposite to each other in the first direction DR1, and second repair initialization lines RVIL2 extending from both sides (e.g., opposite sides) of the first common line CL1′, which are opposite to each other in the first direction DR1.

An arrangement form of the first common line CL1, the (2-1)^{th} common line CL2-1, the (2-2)^{th} common line CL2-2, and the first repair initialization lines RVIL1 may be the same or substantially the same as an arrangement form of the first common line CL1′, the (2-1)^{th} common line CL2-1′, the (2-2)^{th} common line CL2-2′, and the second repair initialization lines RVIL2.

Thus, hereinafter, configurations of the first common line CL1, the (2-1)^{th} common line CL2-1, the (2-2)^{th} common line CL2-2, and the first repair initialization lines RVIL1 will be mainly described in more detail, and configurations of the first common line CL1′, the (2-1)^{th} common line CL2-1′, the (2-2)^{th} common line CL2-2′, and the second repair initialization lines RVIL2 will be briefly described.

Referring to FIGS. 9 and 11A to 11D, the first vertical initialization lines VL1 and the first horizontal initialization lines HL1 may be disposed in the display area DA. The first vertical initialization lines VL1 may extend in the second direction DR2, and may be arranged along the first direction DR1. The first horizontal initialization lines HL1 may extend in the first direction DR1, and may be arranged along the second direction DR2.

In the display area DA, the first vertical initialization lines VL1 and the first horizontal initialization lines HL1 may extend to cross or intersect each other. The first vertical initialization lines VL1 and the first horizontal initialization lines HL1 may be arranged to define a matrix shape.

The first vertical initialization lines VL1 may be disposed adjacent to the first side SI1, the first rounded corner CR1, and the second rounded corner CR2, and may extend in the second direction DR2. The first vertical initialization lines VL1 may extend toward the third rounded corners CR3 and the fourth side SI4.

The first vertical initialization lines VL1 may be disposed between the first rounded corner CR1 and one third rounded corner CR3 that are opposite to each other in the second direction DR2. Further, the first vertical initialization lines VL1 may be disposed between the second rounded corner CR2 and the other third rounded corner CR3 that are opposite to each other in the second direction DR2.

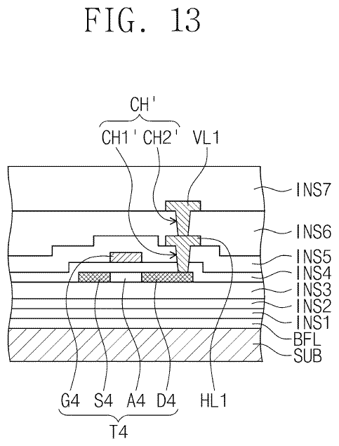

The first vertical initialization lines VL1 may be connected to the first horizontal initialization lines HL1. Contact holes CH′ may be defined at intersection points (e.g., crossing points) between the first vertical initialization lines VL1 and the first horizontal initialization lines HL1, and the first vertical initialization lines VL1 may be electrically connected to the first horizontal initialization lines HL1 through the contact holes CH′. A configuration of the contact holes CH′ will be described in more detail below with reference to FIG. 13.

The first vertical initialization lines VL1 may be connected to the pixels PX. For example, the first vertical initialization lines VL1 may be connected to the pixels PX through the first horizontal initialization lines HL1. This configuration will be described in more detail below with reference to FIGS. 12A and 12B.

The common line CL may be disposed adjacent to at least one side and at least one rounded corner that are adjacent to each other. The first vertical initialization lines VL1 may be disposed adjacent to the at least one side and the at least one rounded corner that are adjacent to each other, and may be connected to the common line CL.

For example, the common line CL may be disposed in the non-display area NDA, and may be adjacent to the first side SI1, the first rounded corner CR1, and the second rounded corner CR2. The first vertical initialization lines VL1 may be disposed adjacent to the first side SI1, the first rounded corner CR1, and the second rounded corner CR2, may extend to the non-display area NDA, and may be connected to the common line CL.

The first vertical initialization lines VL1 may extend from the common line CL in the second direction DR2, and may be connected to the pixels PX within the display area DA. The second direction DR2 may be defined as a direction that crosses or intersects an extension direction (e.g., the first direction DR1) of the first side SI1.

The first common line CL1 may be disposed in the non-display area NDA. The first common line CL1 may be disposed adjacent to the first side SI1. The first common line CL1 may extend in the first direction DR1.

The (2-1)^{th} common line CL2-1 may be disposed in the non-display area NDA. The (2-1)^{th} common line CL2-1 may be adjacent to the first rounded corner CR1, and may have a curved shape corresponding to the first rounded corner CR1. However, the present disclosure is not limited thereto, and the (2-1)^{th} common line CL2-1 may have a straight shape.

The (2-2)^{th} common line CL2-2 may be disposed in the non-display area NDA. The (2-2)^{th} common line CL2-2 may be adjacent to the second rounded corner CR2, and may have a curved shape corresponding to the second rounded corner CR2. However, the present disclosure is not limited thereto, and the (2-2)^{th} common line CL2-2 may have a straight shape.

Referring to FIGS. 11A and 11B, the (2-1)^{th} common line CL2-1 may extend between the scan driver SDV and the first rounded corner CR1. The (2-1)^{th} common line CL2-1 may be disposed between the scan driver SDV and the first rounded corner CR1. The (2-1)^{th} common line CL2-1 may be closer to the first rounded corner CR1 than to the scan driver SDV.

The (2-2)^{th} common line CL2-2 may extend between the light emission driver EDV and the second rounded corner CR2. The (2-2)^{th} common line CL2-2 may be disposed between the light emission driver EDV and the second rounded corner CR2. The (2-2)^{th} common line CL2-2 may be closer to the second rounded corner CR2 than to the light emission driver EDV.

Referring to FIGS. 9 and 11A to 11D, the (2-1)^{th} common line CL2-1 and the (2-2)^{th} common line CL2-2 may extend from the first common line CL1. The (2-1)^{th} common line CL2-1 may extend from one side of the first common line CL1 in a curved shape, and the (2-2)^{th} common line CL2-2 may extend from the other side of the first common line CL1 in a curved shape.

The first vertical initialization lines VL1 may extend to the non-display area NDA, and may be connected to the first common line CL1, the (2-1)^{th} common line CL2-1, and the (2-2)^{th} common line CL2-2.

Among the first vertical initialization lines VL1, the first vertical initialization lines VL1 adjacent to the first side SI1 may be connected to the first common line CL1, and may extend from the first common line CL1 in the second direction DR2. The first vertical initialization lines VL1 adjacent to the first side SI1 may extend toward the fourth side SI4.

Among the first vertical initialization lines VL1, the first vertical initialization lines VL1 adjacent to the first rounded corner CR1 may be connected to the (2-1)^{th} common line CL2-1, and may extend from the (2-1)^{th} common line CL2-1 in the second direction DR2. The first vertical initialization lines VL1 adjacent to the first rounded corner CR1 may extend toward the third rounded corner CR3 opposite to the first rounded corner CR1 in the second direction DR2.

Among the first vertical initialization lines VL1, the first vertical initialization lines VL1 adjacent to the second rounded corner CR2 may be connected to the (2-2)^{th} common line CL2-2, and may extend from the (2-2)^{th} common line CL2-2 in the second direction DR2. The first vertical initialization lines VL1 adjacent to the second rounded corner CR2 may extend toward the third rounded corner CR3 opposite to the second rounded corner CR2 in the second direction DR2.

The first horizontal initialization lines HL1 may be adjacent to the first rounded corner CR1, the second side SI2, and the third rounded corner CR3 connected to the second side SI2, and may extend in the first direction DR1. The first horizontal initialization lines HL1 may extend toward the second rounded corner CR2, the third side SI3, and the third rounded corner CR3 connected to the third side SI3.

The first common line CL1 may be connected to first pads PD1. The first pads PD1 may be adjacent to a lower portion of the display panel DP, and the data drivers DDV may be disposed between the first pads PD1. However, the arrangement positions of the first pads PD1 are not limited thereto. The first pads PD1 may receive the first initialization voltage VINT.

The common line CL may not be disposed in the non-display area NDA adjacent to the second side SI2, the third side SI3, the third rounded corners CR3, and the fourth side SI4.

Referring to FIG. 9, the first repair initialization lines RVIL1 may extend between the display area DA and the scan driver SDV, and between the display area DA and the light emission driver EDV. The first repair initialization lines RVIL1 may be adjacent to the scan driver SDV and the light emission driver EDV. The first repair initialization lines RVIL1 may extend outward from the (2-1)^{th} common line CL2-1 and the (2-2)^{th} common line CL2-2.

The display panel DP may include a plurality of repair pixel circuits RPC. For convenience of illustration, the repair pixel circuits RPC are not illustrated in FIG. 9 as a reduced view, but the repair pixel circuits are illustrated in FIGS. 11A to 11D as enlarged views.

Referring to FIGS. 11A to 11D, the repair pixel circuits RPC may be disposed between the display area DA and the scan driver SDV, and between the display area DA and the light emission driver EDV. The repair pixel circuits RPC may be adjacent to the scan driver SDV and the light emission driver EDV. The repair pixel circuits RPC may be disposed between the scan driver SDV and the first repair initialization line RVIL1 adjacent to the scan driver SDV. Further, the repair pixel circuits RPC may be disposed between the light emission driver EDV and the first repair initialization line RVIL1 adjacent to the light emission driver EDV.

The first repair initialization lines RVIL1 may be connected to the repair pixel circuits RPC. Each of the repair pixel circuits RPC may have the same or substantially the same configuration as that of the pixel circuit PC described above with reference to FIG. 5.

The pixel circuits PC of some of the pixels PX may be damaged. The damaged pixel circuits PC may be connected to some of the repair pixel circuits RPC through repair lines.

Because the repair pixel circuits RPC may also be driven in the same or substantially the same manner as that of the pixel circuits PC, the first initialization voltage VINT may also be applied to the repair pixel circuits RPC. The first repair initialization lines RVIL1 may be connected to the repair pixel circuits RPC to apply the first initialization voltage VINT to the repair pixel circuits RPC.

Referring to FIG. 10, the second vertical initialization lines VL2 may extend in the second direction DR2, and the second horizontal initialization lines HL2 may extend in the first direction DR1. The second vertical initialization lines VL2 and the second horizontal initialization lines HL2 may be disposed in the display area DA, and may cross or intersect each other.

The second vertical initialization lines VL2 may be adjacent to the first side SI1, the first rounded corner CR1, and the second rounded corner CR2, and may extend in the second direction DR2. The second horizontal initialization lines HL2 may be adjacent to the first rounded corner CR1, the second side SI2, and the third rounded corner CR3 connected to the second side SI2, and may extend in the first direction DR1.

The second vertical initialization lines VL2 may be connected to the second horizontal initialization lines HL2 through contact holes CH′ defined at intersection points between the second vertical initialization lines VL2 and the second horizontal initialization lines HL2. The second vertical initialization lines VL2 may be connected to the pixels PX through the second horizontal initialization lines HL2, and this configuration will be described in more detail below with reference to FIGS. 12A and 12B.

The first common line CL1′, the (2-1)^{th} common line CL2-1′, and the (2-2)^{th} common line CL2-2′ may be disposed in the non-display area NDA. The first common line CL1′ may be adjacent to the first side SI1, and may extend in the first direction DR1. The (2-1)^{th} common line CL2-1′ may be adjacent to the first rounded corner CR1, and may have a curved shape corresponding to the first rounded corner CR1. The (2-2)^{th} common line CL2-2′ may be adjacent to the second rounded corner CR2, and may have a curved shape corresponding to the second rounded corner CR2.

The (2-1)^{th} common line CL2-1′ and the (2-2)^{th} common line CL2-2′ may extend from the first common line CL1′. The second vertical initialization lines VL2 may extend to the non-display area NDA, and may be connected to the first common line CL1′, the (2-1)^{th} common line CL2-1′, and the (2-2)^{th} common line CL2-2′. The second vertical initialization lines VL2 may extend from the first common line CL1′, the (2-1)^{th} common line CL2-1′, and the (2-2)^{th} common line CL2-2′ in the second direction DR2, and may be connected to the pixels PX within the display area DA.

The first common line CL1′ may be connected to second pads PD2 that are disposed adjacent to the lower portion of the display panel DP, and may receive the second initialization voltage VAINT.

The common line CL′ may not be disposed in the non-display area NDA adjacent to the second side SI2, the third side SI3, the third rounded corners CR3, and the fourth side SI4.

The second repair initialization lines RVIL2 may extend between the display area DA and the scan driver SDV, and between the display area DA and the light emission driver EDV. The second repair initialization lines RVIL2 may be adjacent to the scan driver SDV and the light emission driver EDV. The second repair initialization lines RVIL2 may extend outward from the (2-1)^{th} common line CL2-1′ and the (2-2)^{th} common line CL2-2′.

Although not illustrated in the enlarged view of FIG. 10, the second repair initialization lines RVIL2, like the first repair initialization lines RVIL1, may be connected to the repair pixel circuits RPC described above with reference to FIGS. 11A to 11D. Thus, the repair pixel circuits RPC may receive the second initialization voltage VAINT through the second repair initialization lines RVIL2.

FIG. 12A is a plan view illustrating a connection configuration between the first and second initialization lines and the pixels at a center of the display panel. FIG. 12B is a plan view illustrating a connection configuration between the first and second initialization lines and the pixels adjacent to the first rounded corner.

Referring to FIGS. 12A and 12B, the display panel DP may include a plurality of pixel groups PG. Illustratively, the pixel groups PG may be arranged along the first direction DR1 and the second direction DR2 in a matrix form. The first direction DR1 may correspond to a row, and the second direction DR2 may correspond to a column. Thus, the pixel groups PG may be arranged into a plurality of rows and a plurality of columns.

Each of the pixel groups PG may include a first pixel PX1, a second pixel PX2, and a third pixel PX3. Each of the first, second, and third pixels PX1, PX2, and PX3 may correspond to the pixel PXij described above with reference to FIGS. 5 and 7.

The first pixel PX1, the second pixel PX2, and the third pixel PX3 may display different colors from each other. For example, the first pixel PX1 may display a red color, the second pixel PX2 may display a green color, and the third pixel PX3 may display a blue color.

The first vertical initialization lines VL1 and the second vertical initialization lines VL2 may extend in the second direction DR2, and may be alternately disposed along the first direction DR1. The first and second vertical initialization lines VL1 and VL2 may be alternately disposed on sides of the pixel groups PG arranged in columns. Illustratively, the first and second vertical initialization lines VL1 and VL2 may be alternately disposed on right sides of the pixel groups PG arranged in columns, but the arrangement positions of the first and second vertical initialization lines VL1 and VL2 are not limited thereto.

The first horizontal initialization lines HL1 and the second horizontal initialization lines HL2 may be disposed adjacent to each other in pairs. A pair of the first horizontal initialization line HL1 and the second horizontal initialization line HL2 that are adjacent to each other may be disposed adjacent to lower portions of the pixel groups PG disposed in corresponding rows, but the arrangement positions of the first and second horizontal initialization lines HL1 and HL2 are not limited thereto.

The first horizontal initialization lines HL1 may be connected to the first, second, and third pixels PX1, PX2, and PX3, and to the first vertical initialization lines VL1. The first vertical initialization lines VL1 may be connected to the first, second, and third pixels PX1, PX2, and PX3 through the first horizontal initialization lines HL1.

The second horizontal initialization lines HL2 may be connected to the first, second, and third pixels PX1, PX2, and PX3, and to the second vertical initialization lines VL2. The second vertical initialization lines VL2 may be connected to the first, second, and third pixels PX1, PX2, and PX3 through the second horizontal initialization lines HL2.

The first, second, and third pixels PX1, PX2, and PX3 that are adjacent to the first rounded corner CR1 may be connected the first and second vertical initialization lines VL1 and VL2 that are adjacent to the first rounded corner CR1 through the first and second horizontal initialization lines HL1 and HL2.

FIG. 13 is a view illustrating a cross section of a first vertical initialization line and a first horizontal initialization line corresponding to one contact hole illustrated in FIG. 9.

Referring to FIG. 13, the first horizontal initialization line HL1 may be disposed on the fifth insulating layer INS5, and the sixth insulating layer INS6 may be disposed on the first horizontal initialization line HL1. The first vertical initialization line VL1 may be disposed on the sixth insulating layer INS6, and the seventh insulating layer INS7 may be disposed on the first vertical initialization line VL1.

Depending on the cross-sectional structure, the first vertical initialization line VL1 and the first horizontal initialization line HL1 may be disposed at (e.g., in or on) different layers from each other. The first vertical initialization line VL1 may be disposed above the first horizontal initialization line HL1.

The first horizontal initialization line HL1 may be connected to the fourth drain area D4 of the fourth transistor T4 through a first contact hole CH1′ defined by (e.g., penetrating) the fourth and fifth insulating layers INS4 and INS5. The first vertical initialization line VL1 may be connected to the first horizontal initialization line HL1 through a second contact hole CH2′ defined by (e.g., penetrating) the sixth insulating layer INS6. The contact hole CH′ described above with reference to FIG. 9 may include the first and second contact holes CH1′ and CH2′ illustrated in FIG. 13.

The first vertical initialization line VL1 may be connected to the fourth transistor T4 through the first horizontal initialization line HL1. The first initialization voltage VINT may be provided to the fourth transistor T4 through the first vertical initialization line VL1 and the first horizontal initialization line HL1.

The second vertical initialization line VL2 and the second horizontal initialization line HL2 may be disposed at (e.g., in or on) the same layer as those of the first vertical initialization line VL1 and the first horizontal initialization line HL1. Further, the second vertical initialization line VL2 and the second horizontal initialization line HL2 may be connected in or substantially connected in the same or substantially the same connection structure as that of the first vertical initialization line VL1 and the first horizontal initialization line HL1. The second vertical initialization line VL2 may be connected to the seventh transistor T7 through the second horizontal initialization line HL2.

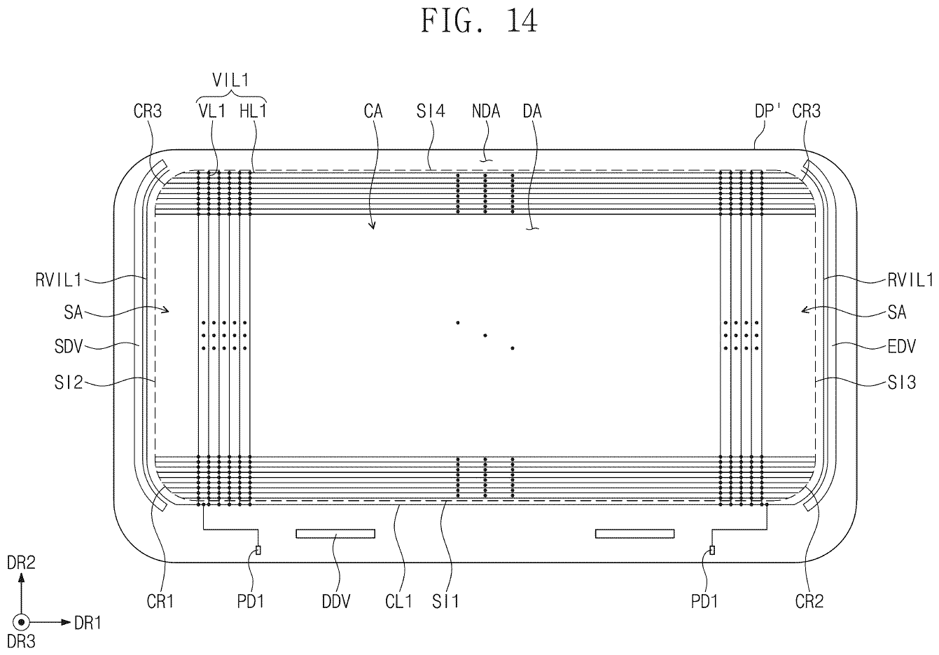

FIG. 14 is a view illustrating a configuration of a display panel according to a comparative example.

Illustratively, FIG. 14 is a plan view corresponding to that of FIG. 9, and hereinafter, configurations illustrated in FIG. 14 will be described in more detail while focusing on the differences from the configurations described above with reference to FIG. 9.

Referring to FIG. 14, the first common line CL1 may be disposed adjacent to the first side SI1. The first vertical initialization lines VL1 may be connected to the first common line CL1. Unlike that of FIG. 9, the first common line CL1 connected to the first vertical initialization lines VL1 may not be disposed adjacent to the first rounded corner CR1 and the second rounded corner CR2.

The first vertical initialization lines VL1 may not be disposed adjacent to the first rounded corner CR1 and the second rounded corner CR2. The first vertical initialization lines VL1 may not be disposed between the first rounded corner CR1 and the third rounded corner CR3 that are opposite to each other in the second direction DR2, and between the second rounded corner CR2 and the third rounded corner CR3 that are opposite to each other in the second direction DR2.

Areas between the first rounded corner CR1 and the third rounded corner CR3 that are opposite to each other in the second direction DR2 and between the second rounded corner CR2 and the third rounded corner CR3 that are opposite to each other in the second direction DR2 may be defined as side areas SA. An area between the side areas SA may be defined as a central area CA, and the first vertical initialization lines VL1 may be disposed in the central area CA.

When the first vertical initialization lines VL1 are not disposed in the side areas SA and the first vertical initialization lines VL1 are disposed in the central area CA, a line resistance for the pixels PX disposed in the central area CA and a line resistance for the pixels PX disposed in the side areas SA may be different from each other. In this case, a difference between image qualities of the pixels PX disposed in the central area CA and the pixels PX disposed in the side areas SA may occur, and thus, a display quality may be degraded.

In the display panel DP according to the comparative example, the second initialization line VIL2 and the common line connected to the second initialization line VIL2 may also be disposed in the same or substantially the same form as those of the first initialization line VIL1 and the first common line CL1. Thus, as described above, the display quality may be degraded.

Referring to FIGS. 9 and 10, in some embodiments of the present disclosure, the first vertical initialization lines VL1 and the second vertical initialization lines VL2 may also be disposed in the side areas SA described above with reference to FIG. 14. In this case, the line resistance for the pixels PX disposed in the central area CA and the line resistance for the pixels PX disposed in the side areas SA may become more uniform. Thus, the difference between the image qualities of the pixels PX disposed in the central area CA and the pixels PX disposed in the side areas SA may be decreased, and thus, the display quality may be improved.

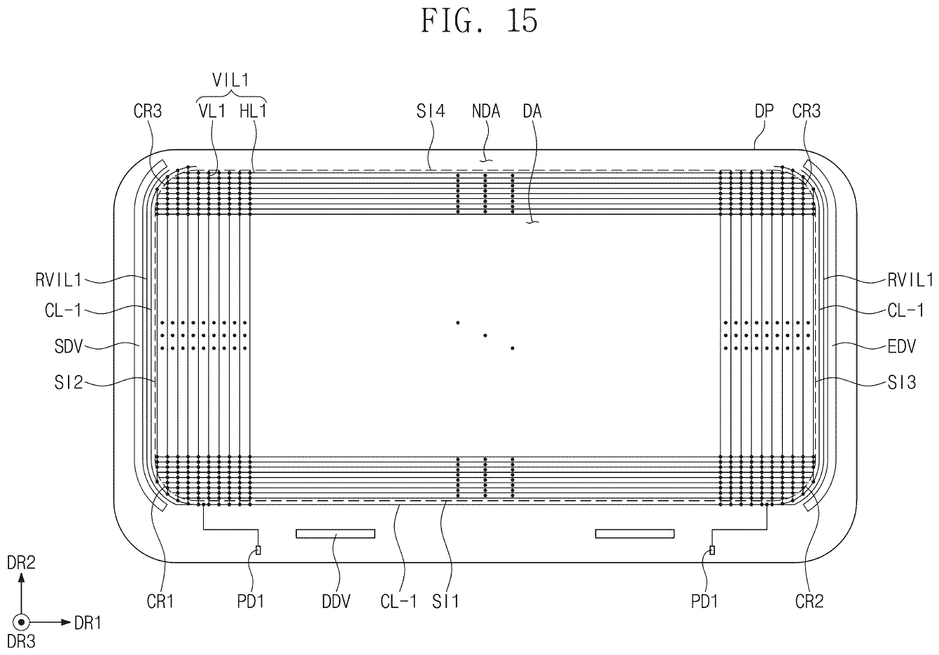

FIGS. 15 through 17 are views illustrating configurations of common lines according to one or more embodiments of the present disclosure.

Illustratively, FIGS. 15 to 17 are illustrated in a plane corresponding to that of FIG. 9, and configurations illustrated in FIGS. 15 to 17 will be described in more detail below while focusing on the differences from the configurations described above with reference to FIG. 9.

Further, FIGS. 15 to 17 illustrate common lines CL-1, CL-2, and CL-3 connected to the first initialization line VIL1, but the common lines connected to the second initialization line VIL2 may also have the same or substantially the same forms as those of the common lines CL-1, CL-2, and CL-3.

Referring to FIG. 15, the common line CL-1 may extend along the first, second, and third sides SI1, SI2, and SI3, and along the first, second, and third rounded corners CR1, CR2, and CR3. The common line CL-1 may be disposed adjacent to the first, second, and third sides SI1, SI2, and SI3, and the first, second, and third rounded corners CR1, CR2, and CR3.

The first vertical initialization lines VL1 may be connected to the common line CL-1. As compared to those of FIG. 9, the first vertical initialization lines VL1 may be further connected to the common line CL-1 adjacent to the third rounded corners CR3.

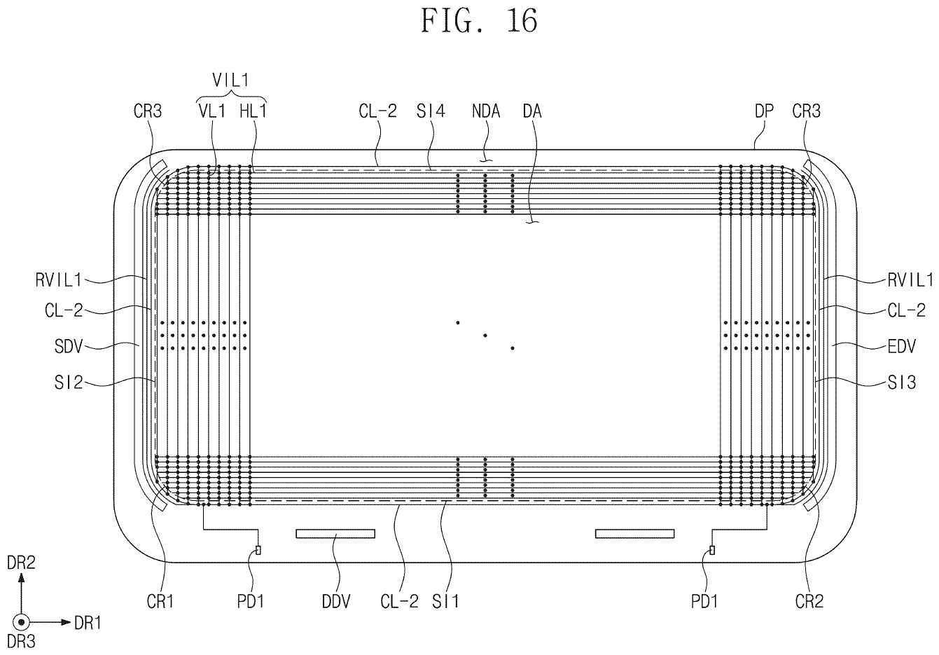

Referring to FIG. 16, the common line CL-2 may be disposed to surround (e.g., around a periphery of) the display area DA. Thus, as compared to that of FIG. 15, the common line CL-2 may further extend along the fourth side SI4.

The first vertical initialization lines VL1 may be connected to the common line CL-2. As compared to those of FIG. 15, the first vertical initialization lines VL1 may extend to the non-display area NDA, and may be further connected to the common line CL-2 adjacent to the fourth side SI4.

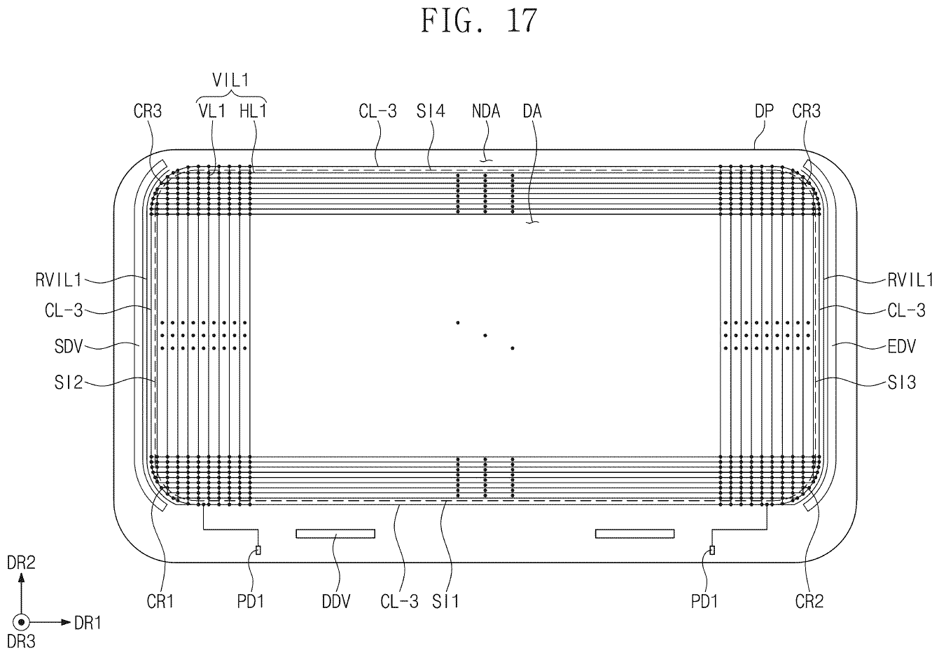

Referring to FIG. 17, the common line CL-3 may be disposed to surround (e.g., around a periphery of) the display area DA. The first vertical initialization lines VL1 may extend to the non-display area NDA, and may be connected to the common line CL-3. The first horizontal initialization lines HL1 may extend to the non-display area NDA, and may be connected to the common line CL-3.

According to some embodiments of the present disclosure, vertical initialization lines connected to pixels may be disposed not only on a first side extending in a first direction, but also on first and second rounded corners connected to both ends (e.g., opposite ends) of the first side, and thus, line resistances for the pixels in a display area may be more uniformly formed. Accordingly, a display quality of the display device may be improved.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a plurality of pixels in a display area;
a plurality of scan lines connected to the pixels;
a plurality of data lines connected to the pixels;
a plurality of vertical initialization lines connected to the pixels; and
a common line in a non-display area around the display area,
wherein the display area comprises:
a first side extending in a first direction;
a second side adjacent to one end of the first side, and extending in a second direction crossing the first direction; and
a first rounded corner connecting the one end of the first side to one end of the second side that is adjacent to the one end of the first side,
wherein the common line is adjacent to the first side and the first rounded corner, and
wherein the vertical initialization lines are adjacent to the first side and the first rounded corner, are connected to the common line, and extend from the common line in the second direction.

2. The display device of claim 1, wherein the common line is not located in the non-display area adjacent to the second side.

3. The display device of claim 1, wherein the common line comprises:
a first common line in the non-display area, and adjacent to the first side; and
a (2-1)^{th} common line in the non-display area, and adjacent to the first rounded corner.

4. The display device of claim 3, wherein the first common line extends in the first direction, and
wherein the (2-1)^{th} common line extends from the first common line, and has a curved shape corresponding to the first rounded corner.

5. The display device of claim 3, wherein the first common line is connected to a pad configured to receive an initialization voltage.

6. The display device of claim 3, further comprising:
a scan driver in the non-display area, adjacent to the second side and the first rounded corner, and connected to the scan lines.

7. The display device of claim 6, wherein the (2-1)^{th} common line is located between the scan driver and the first rounded corner.

8. The display device of claim 6, further comprising:
a repair initialization line extending from the first common line between the display area and the scan lines; and
a repair pixel circuit between the display area and the scan lines, and located adjacent to the scan driver,
wherein the repair initialization line is connected to the repair pixel circuit.

9. The display device of claim 3, wherein the display area further comprises:
a third side adjacent to another end of the first side, and extending in the second direction; and
a second rounded corner connecting the other end of the first side to one end of the third side adjacent to the other end of the first side,
wherein the common line further comprises a (2-2)^{th} common line in the non-display area, and adjacent to the second rounded corner, and
wherein the vertical initialization lines are further located adjacent to the second rounded corner, are connected to the (2-2)^{th} common line, and extend from the (2-2)^{th} common line in the second direction.

10. The display device of claim 9, wherein the common line is not located in the non-display area adjacent to the third side.

11. The display device of claim 9, wherein the (2-2)^{th} common line extends from the first common line, and has a curved shape corresponding to the second rounded corner.

12. The display device of claim 9, further comprising:
a plurality of light emitting lines connected to the pixels; and
a light emission driver in the non-display area, adjacent to the third side and the second rounded corner, and connected to the light emitting lines.

13. The display device of claim 12, wherein the (2-2)^{th} common line is located between the light emission driver and the second rounded corner.

14. The display device of claim 1, further comprising:
a plurality of horizontal initialization lines in the display area, and extending to cross the vertical initialization lines.

15. The display device of claim 14, wherein the horizontal initialization lines are connected to the vertical initialization lines and to the pixels.

16. The display device of claim 15, wherein the vertical initialization lines and the horizontal initialization lines are located at different layers from each other.

17. The display device of claim 16, wherein the vertical initialization lines are located above the horizontal initialization lines.

18. The display device of claim 14, wherein the common line surrounds around the display area, and
wherein the vertical initialization lines and the horizontal initialization lines extend to the non-display area, and are connected to the common line.

19. A display device comprising:
a plurality of pixels in a display area;
a plurality of scan lines connected to the pixels;
a plurality of data lines connected to the pixels;
a common line in a non-display area around the display area; and
a plurality of vertical initialization lines connected to the pixels,
wherein the display area comprises:
a first side extending in a first direction;
a second side and a third side adjacent to opposite ends of the first side, and extending in a second direction crossing the first direction;
a first rounded corner connecting the first side and the second side to each other; and
a second rounded corner connecting the first side and the second side to each other,
wherein the common line is adjacent to the first side, the first rounded corner, and the second rounded corner, and
wherein the vertical initialization lines are adjacent to the first side, the first rounded corner, and the second rounded corner, are connected to the common line, and extend from the common line in the second direction.

20. The display device of claim 19, wherein the common line is not located in a non-display area adjacent to each of the second side and the third side.

21. A display device comprising:
a plurality of pixels located inside a display area, the display area comprising:
sides of a quadrangle extending in a first direction and a second direction crossing the first direction; and
rounded corners connecting the sides to one another;
a plurality of scan lines connected to the pixels;
a plurality of data lines connected to the pixels;
a common line in a non-display area around the display area, and adjacent to at least one side and at least one rounded corner that are adjacent to each other from among the sides and the rounded corners; and
a plurality of vertical initialization lines adjacent to the at least one side and the at least one rounded corner, and connected to the pixels and the common line,
wherein the vertical initialization lines extend from the common line in a direction crossing an extension direction of the at least one side.
